(19) United States
(12) Patent Application Publication
(10) Pub. No.: US 2024/0301282 A1
(43) Pub. Date: Sep. 12, 2024

(54) POLYCYCLIC AROMATIC COMPOUND, COLOR CONVERSION COMPOSITION, COLOR CONVERSION SHEET, LIGHT SOURCE UNIT, DISPLAY AND LIGHTING DEVICE

(71) Applicant: Toray Industries, Inc., Tokyo (JP)

(72) Inventor: Yasunori Ichihashi, Otsu-shi, Shiga (JP)

(73) Assignee: Toray Industries, Inc., Tokyo (JP)

(21) Appl. No.: 18/281,638

(22) PCT Filed: Apr. 11, 2022
(86) PCT No.: PCT/JP2022/017461

§ 371 Date: Sep. 12, 2023

(30) Foreign Application Priority Data
Apr. 28, 2021 (JP) 2021-075673
May 14, 2021 (JP) 2021-082082

(51) Int. Cl. C09K 11/06; H10K 59/38; H10K 101/40

(52) U.S. Cl. CPC C09K 11/06; H10K 59/38; C09K 2211/104; H10K 2101/40

(57) ABSTRACT

A polycyclic aromatic compound according to one aspect of the present invention is a compound which, when exposed to excitation light, is observed to emit light having a peak wavelength in the range of 500 nm to 750 nm, has a HOMO level of not more than −5.7 eV, and emits delayed fluorescence.

### CROSS REFERENCE TO RELATED APPLICATIONS

This application is the U.S. National Phase of PCT/JP2022/017461, filed Apr. 11, 2022, which claims priority to Japanese Patent Application No. 2021-075673, filed Apr. 28, 2021 and Japanese Patent Application No. 2021-082082, filed May 14, 2021, the disclosures of these applications being incorporated herein by reference in their entireties for all purposes.

### FIELD OF THE INVENTION

The present invention relates to a polycyclic aromatic compound, a color conversion composition, a color conversion sheet, a light source unit, a display, and a lighting device.

### BACKGROUND OF THE INVENTION

Studies are vigorously conducted to apply full-color technology based on the color conversion technique to liquid crystal displays, organic EL displays, lighting devices, and the like. Color conversion is the conversion of the light emitted by an illuminant to light of a longer wavelength, and the conversion of blue light to green light or red light is an example of color conversion.

A sheet formed of a composition having a color conversion function (hereinafter referred to as a “color conversion composition”) can be combined with, for example, a blue light source to convert the light from the blue light source into the three primary colors of blue, green, and red, that is, white light. Such a white light source formed by combining a blue light source and a sheet having a color conversion function (hereinafter referred to as a “color conversion sheet”) can be used as a light source unit, and the light source unit can be combined with a liquid crystal driver and a color filter to produce a full-color display. In addition, without a liquid crystal driver, the light source unit can be used directly as a white light source, for example, for LED illumination.

Improving color reproduction accuracy has been a problem with liquid crystal displays. High color purity of blue, green, and red, achieved by reducing the half-width of the emission spectrum of a light source unit with respect to blue, green, and red light, is effective in improving color reproduction. As a means of solving this problem, a technique using semiconductor nanocrystals made of inorganic semiconductor particles as a component of a color conversion composition has been proposed (see, for example, Patent Literature 1). While this technique using semiconductor nanocrystals certainly reduces the half-width of the emission spectrum with respect to green and red light and improves the color reproduction, the semiconductor nanocrystals are sensitive to heat, moisture, and oxygen and have insufficient durability.

In addition, a technique using an organic luminescent material instead of semiconductor nanocrystals as a component of a color conversion composition has also been proposed. As an example of the technique using an organic luminescent material as a component of a color conversion composition, a technique using a pyrromethene derivative has been disclosed (see, for example, Patent Literature 1 and 2).

### PATENT LITERATURE

Patent Literature 1: JP 2011-241160 A
Patent Literature 2: JP 2014-136771 A

### SUMMARY OF THE INVENTION

However, color conversion compositions produced by using any of the organic luminescent materials have been inadequate from the viewpoint of increasing color reproduction and durability. In particular, there have been insufficient technologies available to provide both green light emission with high color purity and high durability.

An object of the present invention to be solved is to provide an organic luminescent material suitable as a color conversion material usable for displays such as liquid crystal display and lighting devices such as LED light, thereby achieving both high color reproduction accuracy and high durability.

That is, in order to solve the problems described above and to achieve the object of the present invention, a polycyclic aromatic compound according to the present invention is observed to emit light having a peak wavelength in the range of 500 nm to 750 nm when exposed to excitation light, has a HOMO level of not more than −5.7 eV, and emits delayed fluorescence.

In addition, the polycyclic aromatic compound according to the present invention follows the above invention, wherein the polycyclic aromatic compound has a HOMO level of not more than −6.0 eV.

In addition, the polycyclic aromatic compound according to the present invention follows the above invention, wherein the polycyclic aromatic compound has a HOMO level of not more than −6.2 eV.

In addition, the polycyclic aromatic compound according to the present invention follows the above invention, wherein the polycyclic aromatic compound has a HOMO level of not more than −6.5 eV.

In addition, the polycyclic aromatic compound according to the present invention follows the above invention, wherein at the emission peak wavelength of the polycyclic aromatic compound, the half-width of the emission spectrum is not more than 40 nm.

In addition, the polycyclic aromatic compound according to the present invention follows the above invention, wherein the polycyclic aromatic compound is a compound represented by the general formula (1) or the general formula (2)

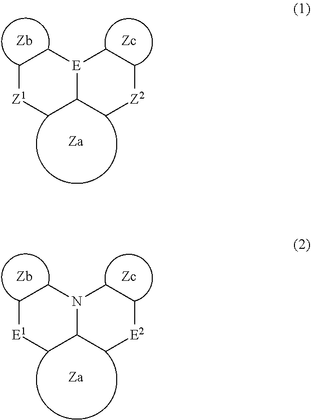

(wherein the rings Za, Zb, and Zc independently represent a substituted or unsubstituted aryl ring having 6 to 30 ring-forming carbon atoms or a substituted or unsubstituted heteroaryl ring having 6 to 30 ring-forming carbon atoms; Z¹ and Z² are independently oxygen, NRa (a nitrogen atom bearing a Ra substituent), or sulfur; in cases where Z¹ is NRa, the substituent Ra, together with the ring Za or the ring Zb, optionally forms a ring; in cases where Z² is NRa, the substituent Ra, together with the ring Za or the ring Zc, optionally forms a ring; E is boron, phosphorus, SiRa (a silicon atom bearing a Ra substituent), or P═O; E¹ and E² are independently BRa (a boron atom bearing a Ra substituent), PRa (a phosphorus atom bearing a Ra substituent), SiRa₂ (a silicon atom bearing two Ra substituents), P(═O)Ra₂ (a phosphine oxide bearing two Ra substituents) or P(═S)Ra₂ (a phosphine sulfide bearing two Ra substituents), or S(═O) or S(═O)₂; in cases where E¹ is BRa, PRa, SiRa₂, P(═O)Ra₂, or P(═S)Ra₂, the substituent Ra, together with the ring Za or the ring Zb, optionally forms a ring; in cases where E² is BRa, PRa, SiRa₂, P(═O)Ra₂, or P(═S)Ra₂, the substituent Ra, together with the ring Za or the ring Zc, optionally forms a ring; the substituents Ra independently represent a substituted or unsubstituted aryl, a substituted or unsubstituted heteroaryl, or a substituted or unsubstituted alkyl).

In addition, the polycyclic aromatic compound according to the present invention follows the above invention, wherein the compound represented by the general formula (1) or the general formula (2) comprises at least one electron-attracting group.

In addition, the polycyclic aromatic compound according to the present invention follows the above invention, wherein the compound represented by the general formula (1) or the general formula (2) comprises two or more electron-attracting groups.

In addition, the polycyclic aromatic compound according to the present invention follows the above invention, wherein the electron-attracting group(s) is/are cyano group(s), acyl group(s), ester group(s), amide group(s), sulfonyl group(s), sulfonate group(s), or sulfonamide group(s).

In addition, the polycyclic aromatic compound according to the present invention follows the above invention, wherein the electron-attracting group(s) is/are ester group(s).

In addition, the polycyclic aromatic compound according to the present invention follows the above invention, wherein the Z¹ and the Z² are oxygen or NRa.

In addition, the polycyclic aromatic compound according to the present invention follows the above invention, wherein the E is boron; and the E¹ and the E² are Bra.

In addition, the polycyclic aromatic compound according to the present invention follows the above invention, wherein the ring Za, the ring Zb, and the ring Zc are benzene rings.

In addition, the polycyclic aromatic compound according to the present invention follows the above invention, wherein the polycyclic aromatic compound is observed to emit light having a peak wavelength in the range of 500 nm to less than 580 nm when exposed to excitation light.

In addition, the polycyclic aromatic compound according to the present invention follows the above invention, wherein the polycyclic aromatic compound is observed to emit light having a peak wavelength in the range of 580 nm to 750 nm when exposed to excitation light.

In addition, a color conversion composition according to the present invention converts incident light into light of a wavelength different from that of the incident light, wherein the color conversion composition comprises any one of the above polycyclic aromatic compounds and a binder resin.

In addition, a color conversion sheet according to the present invention converts incident light into light of a wavelength different from that of the incident light, wherein the color conversion sheet comprises any of the above polycyclic aromatic compounds and a binder resin.

In addition, the color conversion sheet according to the present invention follows the above invention, wherein the color conversion sheet further comprises a barrier film(s).

In addition, a light source unit according to the present invention comprises a light source and any of the above color conversion sheets.

In addition, the light source unit according to the present invention follows the above invention, wherein the light source is a light-emitting diode with a maximum emission wavelength in the range of 430 nm to 500 nm.

In addition, a display according to the present invention comprises any of the above color conversion sheets.

In addition, a lighting device according to the present invention comprises any of the above color conversion sheets.

The present invention is effective in providing a polycyclic aromatic compound and a color conversion composition which are suitable as color conversion materials and can provide both high color reproduction accuracy and high durability. The use of such a polycyclic aromatic compound in a color conversion sheet according to the present invention is effective in achieving both high color reproduction accuracy and high durability. The use of such a color conversion sheet in a light source unit, display, and lighting device according to the present invention is effective in achieving both high color reproduction accuracy and high durability.

### BRIEF DESCRIPTION OF DRAWINGS

FIG. 1 is a schematic cross-sectional view depicting the first example of a color conversion sheet according to an embodiment of the present invention.

FIG. 2 is a schematic cross-sectional view depicting the second example of a color conversion sheet according to an embodiment of the present invention.

FIG. 3 is a schematic cross-sectional view depicting the third example of a color conversion sheet according to an embodiment of the present invention.

FIG. 4 is a schematic cross-sectional view depicting the fourth example of a color conversion sheet according to an embodiment of the present invention.

### DETAILED DESCRIPTION OF EMBODIMENTS OF THE INVENTION

Preferred embodiments of a polycyclic aromatic compound, a color conversion composition, a color conversion sheet, a light source unit, a display, and a lighting device according to the present invention will be specifically described below. However, the present invention is not limited to the following embodiments and various modifications may be made to practice the present invention depending on the purpose or intended use.

### <Polycyclic Aromatic Compound>

A polycyclic aromatic compound according to an embodiment of the present invention is a color conversion material which, for example, a color conversion composition or a color conversion sheet comprises. In particular, the polycyclic aromatic compound is a compound which, when exposed to excitation light, is observed to emit light having a peak wavelength in the range of 500 nm to 750 nm, has a HOMO level of not more than −5.7 eV, and emits delayed fluorescence. Hereinafter, a polycyclic aromatic compound according to an embodiment of the present invention may be referred to as a “polycyclic aromatic compound of the present invention”.

### (Emission Wavelength)

The polycyclic aromatic compound of the present invention is a compound which, when exposed to excitation light, is observed to emit light having a peak wavelength in the range of 500 nm to 750 nm. Preferably, the polycyclic aromatic compound of the present invention is observed to emit light having a peak wavelength in the range of, for example, 500 nm to less than 580 nm when exposed to excitation light. Hereinafter, the emission light observed to have a peak wavelength in the range of 500 nm to less than 580 nm is referred to as “green emission light”.

Preferably, the polycyclic aromatic compound of the present invention emits green light when exposed to excitation light having wavelengths in the range of 430 nm to 500 nm. In general, the higher the energy of the excitation light is, the more likely a luminescent material will degrade. However, the excitation energy of the excitation light in the wavelength range of 430 nm to 500 nm is relatively small. Thus, degradation of a luminescent material in the color conversion composition is prevented, and green light emission with high color purity is obtained.

In addition, the polycyclic aromatic compound of the present invention is preferably observed to emit light having a peak wavelength in the range of 580 nm to 750 nm when exposed to excitation light. Hereinafter, the emission light observed to have a peak wavelength in the range of 580 nm to 750 nm is referred to as “red emission light”.

Preferably, the polycyclic aromatic compound of the present invention emits red light when exposed to excitation light having wavelengths in the range of 430 nm to 500 nm. In general, the higher the energy of the excitation light is, the more likely a luminescent material will degrade. However, the excitation energy of the excitation light in the wavelength range of 430 nm to 500 nm is relatively small. Thus, degradation of a luminescent material in the color conversion composition is prevented, and red light emission with high color purity is obtained.

### (Delayed Fluorescence)

A compound that emits delayed fluorescence is characterized by a small amount of singlet oxygen generated by the rapid transition from the triplet excited state to the singlet excited state. This feature has been shown to prevent degradation of a luminescent material and color change over time, resulting in increased durability. The mechanism of interest is described sequentially.

First, the degradation mechanism of a luminescent material is described. The degradation of a luminescent material causes a color conversion composition to change the color and is induced by singlet oxygen. Singlet oxygen refers to the singlet states of molecular oxygen with two electrons residing in π* orbitals (π antibonding orbitals) and spinning in different directions, that is, the excited states of molecular oxygen with a total spin quantum number of 0. Such excited states include the Σ1 state, in which one electron occupies each of the two π* orbitals with the spins pointing in different directions, and the Δ1 state, in which two electrons spinning in different directions occupy one of the π* orbitals. Singlet oxygen in the Δ1 state has a strong oxidizing power due to the strong electrophilicity of the empty electron orbital. Thus, singlet oxygen is believed to induce the degradation of a luminescent material by oxidation.

Next, the mechanism of singlet oxygen generation is described. It is understood that singlet oxygen is unlikely to be produced directly by optical excitation of the ground state of triplet oxygen because the transition from the ground state of triplet oxygen to the excited states of singlet oxygen is a spin-forbidden transition and is much less likely to occur.

Thus, the generation of singlet oxygen in a color conversion composition is considered to be due to the dye sensitization. That is, singlet oxygen is thought be generated by energy transfer via electron exchange between the triplet excited state of a luminescent material and the ground state of triplet oxygen. The mechanism of singlet oxygen generation is understood as described below.

First, optical excitation of a luminescent material causes a transition from the singlet ground state to the singlet excited state, and furthermore, a fraction of the luminescent material undergoes intersystem crossing from the singlet excited state to the triplet excited state. The transition from the triplet excited state to the singlet ground state that occurs in the luminescent material is a spin-forbidden transition and is therefore typically less likely to occur, and the triplet excited state is long-lived. However, in cases where the ground state of triplet oxygen exists simultaneously, the spin-forbiddenness is relaxed, accompanied by excitation from the ground state of triplet oxygen to the excited states of singlet oxygen, and the triplet excited state of the luminescent material can rapidly deactivate to the singlet ground state. This mechanism is called the Dexter mechanism (electron transfer mechanism).

The Dexter mechanism requires intermolecular electron exchange interactions, stemming from the overlap of wave functions, to proceed. Therefore, it is understood that a direct collision between the energy donor molecule (in this case, the triplet excited state of a luminescent material) and the energy acceptor molecule (in this case, the ground state of triplet oxygen) is required.

As described above, a delayed-fluorescence emitting compound is characterized by a rapid transition from the triplet excited state to the singlet excited state, that is, the short lifetime of the triplet excited state. Therefore, the probability of a direct collision between the triplet excited state of the luminescent material and the ground state of triplet oxygen is reduced, and the generation of singlet oxygen is unlikely.

As seen above, since the polycyclic aromatic compound of the present invention is a delayed-fluorescence emitting compound, the generation of singlet oxygen can be prevented and the durability of a color conversion composition can be improved.

### (Homo Level)

The polycyclic aromatic compound of the present invention is a luminescent material having a HOMO level of not more than −5.7 eV. In cases where a luminescent material has a HOMO level of more than −5.7 eV, oxidization of the luminescent material occurs with repeated excitation-emission cycles due to the interaction with oxygen contained in a composition containing the luminescent material, resulting in quenching of the fluorescence and poor durability. When the HOMO level of a luminescent material is not more than −5.7 eV, the electron density of the luminescent material is reduced. The reduced electron density can make the luminescent material more stable to oxygen and more durable.

From the above, a compound having a HOMO level of not more than −5.7 eV and emitting delayed fluorescence can be used as a luminescent material (a polycyclic aromatic compound of the present invention) to prevent the generation of singlet oxygen and to inhibit the reaction between some generated singlet oxygen and the luminescent material. Thus, the durability of a color conversion composition containing the polycyclic aromatic compound of the present invention as well as the durability of the polycyclic aromatic compound can be improved.

Preferably, the polycyclic aromatic compound of the present invention has a HOMO level of not more than −6.0 eV. In cases where the compound has a HOMO level of not more than −6.0 eV, the electron density of the compound can be further reduced. The reduced electron density can make the polycyclic aromatic compound of the present invention more stable to oxygen and more durable. The HOMO level of the polycyclic aromatic compound of the present invention is more preferably not more than −6.2 eV, still more preferably not more than −6.5 eV, to further enhance the effect described above.

The HOMO level of a compound can be calculated mathematically. In the present invention, the HOMO level of a compound is calculated by simulating the geometry optimization of the compound using the B3LYP density functional theory with the 6-31G(d) basis set and calculating a value based on the optimized geometry using the B3LYP density functional theory with the 6-311++G(d,p) basis set in a general purpose computational chemistry program “Gaussian 16” program package (produced by Gaussian, Inc.).

### (Half-Width)

At the emission peak wavelength of the polycyclic aromatic compound of the present invention, the half-width of the emission spectrum is preferably not more than 40 nm, more preferably not more than 30 nm, still more preferably not more than 25 nm, to achieve light emission with high color purity and a wide color gamut for liquid crystal displays.

### (Chemical Structure)

The polycyclic aromatic compound of the present invention is preferably a compound having a structure represented by the following general formula (1) or general formula (2), but is not limited thereto.

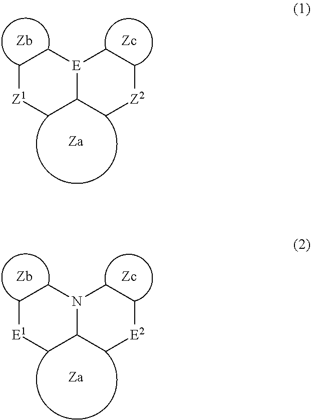

In the general formula (1) or the general formula (2), the rings Za, Zb, and Zc independently represent a substituted or unsubstituted aryl ring having 6 to 30 ring-forming carbon atoms or a substituted or unsubstituted heteroaryl ring having 6 to 30 ring-forming carbon atoms.

In the general formula (1), Z¹ and Z² are independently oxygen, NRa (a nitrogen atom bearing a Ra substituent), or sulfur. In cases where Z¹ is NRa, the substituent Ra, together with the ring Za or the ring Zb, optionally forms a ring. In cases where Z² is NRa, the substituent Ra, together with the ring Za or the ring Zc, optionally forms a ring. E is boron, phosphorus, SiRa (a silicon atom bearing a Ra substituent), or P═O.

In the general formula (2), E¹ and E² are independently BRa (a boron atom bearing a Ra substituent), PRa (a phosphorus atom bearing a Ra substituent), SiRa₂ (a silicon atom bearing two Ra substituents), P(═O)Ra₂ (a phosphine oxide bearing two Ra substituents) or P(═S)Ra₂ (a phosphine sulfide bearing two Ra substituents), or S(═O) or S(═O)₂. In cases where E¹ is BRa, PRa, SiRa₂, P(═O)Ra₂, or P(═S)Ra₂, the substituent Ra, together with the ring Za or the ring Zb, optionally forms a ring. In cases where E² is BRa, PRa, SiRa₂, P(═O)Ra₂, or P(═S)Ra₂, the substituent Ra, together with the ring Za or the ring Zc, optionally forms a ring.

The above substituents Ra independently represent a substituted or unsubstituted aryl, a substituted or unsubstituted heteroaryl, or a substituted or unsubstituted alkyl.

In all of the groups described above, hydrogen can be deuterium. This is also the case for the compounds or substructures thereof described in the following. In addition, all of the groups described above can be substituted or unsubstituted groups. The compounds or substructures thereof described in the following can also be substituted or unsubstituted compounds or substructures thereof. For example, in the following description, a substituted or unsubstituted C₆₋₄₀ aryl group refers to an aryl group whose total number of carbon atoms is from 6 to 40 and includes the number of carbon atoms in the substituent attached to the aryl group. This is also true for other substituent groups with the specified number of carbon atoms.

In cases where any of the above groups are substituted, a preferred substituent is alkyl, cycloalkyl, heterocycle, alkenyl, cycloalkenyl, alkynyl, hydroxyl, thiol, alkoxy, alkylthio, arylether, arylthioether, aryl, heteroaryl, halogen, cyano, aldehyde, carbonyl, acyl, ester, amide, carboxyl, oxycarbonyl, carbamoyl, amino, nitro, silyl, siloxanyl, boryl, or phosphine oxide; furthermore, a specific substituent that is exemplified as preferable in the description of each substituent is preferred. Additionally, these substituents may be further substituted by any of the substituents described above.

The word “unsubstituted” in the phrase “substituted or unsubstituted” refers to substitution with hydrogen or deuterium atoms. The phrase “substituted or unsubstituted” used in the context of the compounds or substructures thereof described below has the same meaning as described above.

Of all the groups described above, alkyl refers to a saturated aliphatic hydrocarbon group, such as methyl, ethyl, n-propyl, isopropyl, n-butyl, sec-butyl, or tert-butyl, and the alkyls may be substituted or unsubstituted. In cases where these hydrocarbon groups are substituted, the additional substituent is not specifically limited and examples of the substituent include alkyl, halogen, aryl, and heteroaryl. The same is true throughout the following description. Furthermore, the number of carbon atoms in the alkyl groups is not specifically limited, but is preferably not less than 1 and not more than 20, more preferably not less than 1 and not more than 8, in view of availability and cost.

“Alkylene” refers to a group derived from a saturated aliphatic hydrocarbon group, such as methyl or ethyl, and having a valence of two or greater, and the alkylenes may be substituted or unsubstituted. Methylene, ethylene, n-propylene, isopropylene, n-butylene, pentylene, and hexylene are preferable alkylenes. The number of carbon atoms in the alkylene groups is not specifically limited, but is preferably not less than 1 and not more than 20 and more preferably not less than 1 and not more than 6.

“Cycloalkyl” refers to a saturated alicyclic hydrocarbon group, such as cyclopropyl, cyclohexyl, norbornyl, or adamantyl, and the cycloalkyls may be substituted or unsubstituted. The number of carbon atoms in the alkyl groups is not specifically limited, but is preferably not less than 3 and not more than 20.

“Cycloalkylene” refers to a group derived from a saturated alicyclic hydrocarbon group, such as cyclopropyl or cyclohexyl, and having a valence of two or greater and the cycloalkylenes may be substituted or unsubstituted. Saturated alicyclic hydrocarbon groups, such as cyclopropylene, cyclohexylene, norbornylene, and adamantylene, are preferable cycloalkylenes. The number of carbon atoms in the cycloalkylene groups is not specifically limited, but is preferably not less than 3 and not more than 20.

“Heterocycle” refers to an aliphatic ring having an atom other than carbon in the ring, such as pyran, piperidine, or cyclic amide, and the heterocycles may be substituted or unsubstituted. The number of carbon atoms in the heterocycle groups is not specifically limited, but is preferably not less than 2 and not more than 20.

“Alkenyl” refers to an unsaturated aliphatic hydrocarbon group containing a double bond, such as vinyl, allyl, or butadienyl, and the alkenyls may be substituted or unsubstituted. The number of carbon atoms in the alkenyl groups is not specifically limited, but is preferably not less than 2 and not more than 20.

“Cycloalkenyl” refers to an unsaturated alicyclic hydrocarbon group containing a double bond, such as cyclopentenyl, cyclopentadienyl, or cyclohexenyl, and the cycloalkenyls may be substituted or unsubstituted. The number of carbon atoms in the cycloalkenyl groups is not specifically limited, but is preferably not less than 3 and not more than 20.

“Alkynyl” refers to an unsaturated aliphatic hydrocarbon group containing a triple bond, such as ethynyl, and the alkynyls may be substituted or unsubstituted. The number of carbon atoms in the alkynyl groups is not specifically limited, but is preferably not less than 2 and not more than 20.

“Alkoxy” refers to a functional group containing an aliphatic hydrocarbon group connected via an ether linkage, such as methoxy, ethoxy, or propoxy, and the aliphatic hydrocarbon group may be substituted or unsubstituted. The number of carbon atoms in the alkoxy groups is not specifically limited, but is preferably not less than 1 and not more than 20.

“Alkylthio” refers to an alkoxy group in which the oxygen atom in the ether linkage is replaced by a sulfur atom. The hydrocarbon group in an alkylthio group may be substituted or unsubstituted. The number of carbon atoms in the alkylthio groups is not specifically limited, but is preferably not less than 1 and not more than 20.

“Arylether” refers to a functional group containing an aromatic hydrocarbon group connected via an ether linkage, such as phenoxy, and the aromatic hydrocarbon group may be substituted or unsubstituted. The number of carbon atoms in the arylether groups is not specifically limited, but is preferably not less than 6 and not more than 40.

“Arylthioether” refers to an arylether group in which the oxygen atom in the ether linkage is replaced by a sulfur atom. The aromatic hydrocarbon group in an arylthioether group may be substituted or unsubstituted. The number of carbon atoms in the arylthioether groups is not specifically limited, but is preferably not less than 6 and not more than 40.

“Aryl” refers to an aromatic hydrocarbon group, such as phenyl, biphenyl, terphenyl, naphthyl, fluorenyl, benzofluorenyl, dibenzofluorenyl, phenanthryl, anthracenyl, benzophenanthryl, benzoanthracenyl, chrysenyl, pyrenyl, fluoranthenyl, triphenylenyl, benzofluoranthenyl, dibenzoanthracenyl, perylenyl, or helicenyl. Among these, phenyl, biphenyl, terphenyl, naphthyl, fluorenyl, phenanthryl, anthracenyl, pyrenyl, fluoranthenyl, and triphenylenyl are preferred. The aryl groups may be substituted or unsubstituted. In cases where substituents are attached to an aryl group, the substituents are linked together to form a cyclic structure. Examples of an aryl group with substituents linked together to form a cyclic structure include spirofluorenyl. The number of carbon atoms in the aryl groups is not specifically limited, but is preferably not less than 6 and not more than 100, more preferably not less than 6 and not more than 50, and still more preferably not less than 6 and not more than 30.

In cases where each substituent is further substituted with an aryl group, the aryl is preferably phenyl, biphenyl, terphenyl, naphthyl, fluorenyl, phenanthryl, or anthracenyl, more preferably phenyl, biphenyl, terphenyl, or naphthyl, and even more preferably phenyl.

“Heteroaryl” refers to an aromatic ring group having one or more atoms other than carbon in the ring, such as pyridyl, furanyl, thienyl, quinolinyl, isoquinolinyl, pyrazinyl, pyrimidyl, pyridazinyl, triazinyl, naphthyridinyl, cinnolinyl, phthalazinyl, quinoxalinyl, quinazolinyl, benzofuranyl, benzothienyl, indolyl, dibenzofuranyl, dibenzothienyl, carbazolyl, benzo-carbazolyl, carbolinyl, indolo-carbazolyl, benzofuro-carbazolyl, benzothieno-carbazolyl, dihydroindeno-carbazolyl, benzoquinolinyl, acridinyl, dibenzoacridinyl, benzoimidazolyl, imidazopyridinyl, benzoxazolyl, benzothiazolyl, or phenanthrolinyl. However, naphthyridinyl refers to any of 1,5-naphthyridinyl, 1,6-naphthyridinyl, 1,7-naphthyridinyl, 1,8-naphthyridinyl, 2,6-naphthyridinyl, or 2,7-naphthyridinyl. The heteroaryl groups may be substituted or unsubstituted. The number of carbon atoms in the heteroaryl groups is not specifically limited, but is preferably not less than 2 and not more than 40 and more preferably not less than 2 and not more than 30.

In cases where each substituent is further substituted with a heteroaryl group, the heteroaryl group is preferably pyridyl, furanyl, thienyl, quinolinyl, pyrimidyl, triazinyl, benzofuranyl, benzothienyl, indolyl, dibenzofuranyl, dibenzothienyl, carbazolyl, benzoimidazolyl, imidazopyridinyl, benzoxazolyl, benzothiazolyl, or phenanthrolinyl, more preferably pyridyl, furanyl, thienyl, or quinolinyl, and even more preferably pyridyl.

“Halogen” refers to an atom selected from fluorine, chlorine, bromine, and iodine. Additionally, carbonyl, carboxyl, oxycarbonyl, and carbamoyl may be substituted or unsubstituted. In this respect, the substituent may be, for example, alkyl, cycloalkyl, aryl, or heteroaryl, and these substituents may be further substituted. The number of carbon atoms in the carbonyl groups is not specifically limited, but is preferably not less than 6 and not more than 40.

“Ester group” refers to a functional group containing, for example, an alkyl group, a cycloalkyl group, an aryl group, or a heteroaryl group connected via an ester linkage, and the substituents may be further substituted. The number of carbon atoms in the ester groups is not specifically limited, but is preferably not less than 1 and not more than 200 and more preferably not less than 1 and not more than 100. More specifically, examples of the ester group include methyl ester groups, such as methoxycarbonyl; ethyl ester groups, such as ethoxycarbonyl; propyl ester groups, such as propoxycarbonyl; butyl ester groups, such as butoxycarbonyl; isopropyl ester groups, such as isopropoxymethoxy carbonyl; hexyl ester groups, such as hexyloxycarbonyl; and phenyl ester groups, such as phenoxycarbonyl.

“Amide group” refers to a functional group containing a substituent, such as alkyl, cycloalkyl, aryl, or heteroaryl, connected via an amide linkage, and the substituents may be further substituted. The number of carbon atoms in the amide groups is not specifically limited, but is preferably not less than 1 and not more than 20. More specifically, examples of the amide group include methylamide, ethylamide, propylamide, butylamide, isopropylamide, hexylamide, and phenylamide.

“Amino group” refers to a substituted or unsubstituted amino group. The amino groups may be substituted or unsubstituted. In cases where an amino group is substituted, the substituent may be, for example, aryl, heteroaryl, linear alkyl, or branched alkyl. Phenyl, naphthyl, pyridyl, and quinolinyl are preferable aryl and heteroaryl groups. These substituents may be further substituted. The number of carbon atoms is not specifically limited, but is preferably not less than 2 and not more than 50, more preferably not less than 6 and not more than 40, and even more preferably not less than 6 and not more than 30.

“Silyl group” refers to, for example, an alkylsilyl group, such as trimethylsilyl, triethylsilyl, tert-butyldimethylsilyl, propyldimethylsilyl, or vinyldimethylsilyl; or an arylsilyl group, such as phenyldimethylsilyl, tert-butyl(diphenyl)silyl, or triphenylsilyl, trinaphthylsilyl. The substituent on the silicon atom may be further substituted. The number of carbon atoms in the silyl groups is not specifically limited, but is preferably not less than 1 and not more than 30.

“Siloxanyl” refers to a group containing a silicon compound connected via an ether linkage, such as trimethylsiloxanyl. The substituent on the silicon atom may be further substituted. The number of carbon atoms in the siloxanyl groups is not specifically limited, but is preferably not less than 1 and not more than 30. In addition, “boryl” refers to a substituted or unsubstituted boryl group. The boryl groups may be substituted or unsubstituted. In cases where a boryl group is substituted, the substituent may be, for example, aryl, heteroaryl, linear alkyl, branched alkyl, arylether, alkoxy, or hydroxyl. Among these, aryl and arylether are preferred. The number of carbon atoms in the boryl groups is not specifically limited, but is preferably not less than 1 and not more than 30.

“Acyl” refers to a functional group containing a substituent, such as alkyl, cycloalkyl, aryl, or heteroaryl, connected via a carbonyl linkage, and the substituents may be further substituted. The number of carbon atoms in the acyl groups is not specifically limited, but is preferably not less than 1 and not more than 20. More specifically, examples of the acyl group include acetyl, propionyl, benzoyl, and acrylyl.

“Sulfonyl” refers to a functional group containing a substituent, such as alkyl, cycloalkyl, aryl, or heteroaryl, connected via a —S(═O)₂— linkage, and the substituents may be further substituted. The number of carbon atoms in the sulfonyl groups is not specifically limited, but is preferably not less than 1 and not more than 30.

“Sulfoxide” refers to a functional group containing a substituent, such as alkyl, cycloalkyl, aryl, or heteroaryl, connected via a —S(═O)— linkage, and the substituents may be further substituted. The number of carbon atoms in the sulfoxide groups is not specifically limited, but is preferably not less than 1 and not more than 30.

In addition, “phosphine oxide group” is a group represented by —P(═O)R¹⁰R¹¹. R¹⁰ and R¹¹ in a phosphine oxide group are selected in the same manner as the substituent Ra described above. The number of carbon atoms in the phosphine oxide groups is not specifically limited, but is preferably not less than 1 and not more than 30.

Examples of the aryl ring having 6 to 30 ring-forming carbon atoms include benzene ring, naphthalene ring, fluorene ring, benzofluorene ring, dibenzofluorene ring, phenanthrene ring, anthracene ring, benzophenanthrene ring, benzoanthracene ring, chrysene ring, pyrene ring, fluoranthene ring, triphenylene ring, benzofluoranthene ring, dibenzoanthracene ring, perylene ring, and helicene ring.

Examples of the heteroaryl ring having 6 to 30 ring-forming carbon atoms include pyridine ring, furan group, thiophene ring, quinoline ring, isoquinoline ring, pyrazine ring, pyrimidine ring, pyridazine ring, naphthyridine ring, cinnoline ring, phthalazine ring, quinoxaline ring, quinazoline ring, benzofuran ring, benzothiophene ring, indole ring, dibenzofuran ring, dibenzothiophene ring, carbazole ring, benzocarbazole ring, carboline ring, indolo-carbazole ring, benzofuro-carbazole ring, benzothieno-carbazole ring, dihydroindeno-carbazole ring, benzoquinoline ring, acridine ring, dibenzoacridine ring, imidazole ring, oxazole ring, thiazole ring, benzoimidazole ring, imidazopyridine ring, benzooxazole ring, benzothiazole ring, and phenanthroline ring.

A compound represented by the general formula (1) or the general formula (2) has a rigid and highly planar structure. Therefore, the compound represented by the general formula (1) or the general formula (2) exhibits a high luminescence quantum yield, and the compound represented by the general formula (1) or the general formula (2) exhibits a small peak half-width of the emission spectrum. Thus, a high color conversion efficiency and a high color purity can be achieved by the compound represented by the general formula (1) or the general formula (2).

In addition, an electron-donating substituent and an electron-accepting substituent are used to tune the HOMO-LUMO localization in the molecule of the compound represented by the general formula (1) or the general formula (2), resulting in an efficient reverse intersystem crossing from the triplet excited state to the singlet excited state. As a result, the compound becomes a delayed-fluorescence emitting compound. Therefore, the durability of the compound represented by the general formula (1) or the general formula (2) can be increased.

Additionally, in cases where the compound represented by the general formula (1) or the general formula (2) has at least one electron-attracting group, the compound represented by the general formula (1) or the general formula (2) has a lower electron density than that in the absence of the electron-attracting group. This increases the stability of the compound represented by the general formula (1) or the general formula (2) against singlet oxygen and, consequently, increases the durability of the compound. Therefore, the compound represented by the general formula (1) or the general formula (2) preferably has at least one electron-attracting group.

Preferably, the compound represented by the general formula (1) or the general formula (2) has at least one electron-attracting group as a substituent on the ring Za, the ring Zb or the ring Zc, or a substituent on a ring formed between the adjacent rings. In an example of the latter case, the compound has an electron-attracting group as a substituent on, for example, a ring formed by a substituent Ra bonded to the ring Zb, where Z¹ is NRa.

Preferably, the compound represented by the general formula (1) or the general formula (2) has two or more electron-attracting groups. This increases the stability of the compound represented by the general formula (1) or the general formula (2) against singlet oxygen to a greater extent and, consequently, further increases the durability of the compound.

In organic electron theory, an electron-attracting group, also called an electron-accepting group, is an atomic group that attracts electrons by the inductive or resonance effect from another atomic group to which the electron-attracting group is substituted. Electron-attracting groups are substituents with a positive value for the Hammett substituent constant (σp (para)). The Hammett substituent constants (σp (para)) can be obtained from Handbook of Chemistry: Pure Chemistry, 5th Edition (p. II-380). In some cases, the phenyl group is positive for the Hammett substituent constant, but the electron-attracting group in the present invention includes no phenyl group.

Preferred examples of the electron-attracting groups include cyano, acyl, ester, amide, sulfonyl, sulfonate, and sulfonamide groups. These groups can efficiently reduce the electron density of the basic structure. Additionally, these groups are moderately polar and therefore increase the solubility of the compound represented by the general formula (1) or the general formula (2) in, for example, a solvent or a resin for the production of a color conversion composition. These are reasons why these groups are preferable. This increases the stability of the compound represented by the general formula (1) or the general formula (2) against singlet oxygen to a greater extent and, consequently, further increases the durability of the compound.

A particularly preferable example of an electron-attracting group is the ester group. When the electron-attracting group is an ester group, the electron density of the basic structure can be moderately reduced without increasing the conjugation of the basic structure. Therefore, the durability of the compound represented by the general formula (1) or the general formula (2) can be further increased without compromising the emission efficiency and color purity.

Among ester groups, fluorine-containing ester groups (ester groups containing a fluorine atom) are much more preferable. For example, an alkyl ester group described above, such as methyl ester, or an aryl ester group described above, such as phenyl ester, is preferably substituted with a fluorine atom or a fluorine-containing group. An example of a methyl ester group substituted with a fluorine atom is, for example, the trifluoromethyl ester group. An example of a phenyl ester group substituted with a fluorine-containing group is, for example, the trifluoromethyl phenyl group or the (3,5-bistrifluoromethylphenyl)phenyl ester group.

In addition, the electron-attracting group is preferably sterically bulky. When the electron-attracting group is bulky, the degree of freedom of molecular motion of the compound represented by the general formula (1) or the general formula (2) is reduced due to the structure of the electron-attracting group, resulting in limited freedom of molecular motion in a resin. Additionally, the electron-attracting group acting as a sterically hindering group allows the compound represented by the general formula (1) or the general formula (2) to have higher stability without inducing any interaction between molecules of the compound. Thus, the sterically bulky electron-attracting group can prevent aggregation of molecules of the compound represented by the general formula (1) or the general formula (2), resulting in increased durability of the compound.

The number of carbon atoms that constitute the electron-attracting group is not specifically limited, but is preferably not less than 2 and not more than 200, more preferably not less than 6 and not more than 200, and even more preferably not less than and not more than 200.

In the general formula (1), Z¹ and Z² are preferably an oxygen atom or NRa, because they efficiently extend the π-conjugation system of a compound represented by the general formula (1), resulting in more efficient reverse intersystem crossing from the triplet excited state to the singlet excited state, thus further increasing the durability of the compound.

In the general formula (1) or the general formula (2), E is preferably a boron atom, and E¹ and E² are preferably Bra, because they efficiently extend the π-conjugation system of the compound represented by the general formula (1) or the general formula (2), resulting in more efficient reverse intersystem crossing from the triplet excited state to the singlet excited state, thus further increasing the durability of the compound.

In the general formula (1) or the general formula (2), the rings Za, Zb, and Zc are preferably benzene rings, because they efficiently extend the π-conjugation system of the compound represented by the general formula (1) or the general formula (2), resulting in more efficient reverse intersystem crossing from the triplet excited state to the singlet excited state, thus further increasing the durability of the compound.

Examples of the polycyclic aromatic compound of the present invention are shown below, but the polycyclic aromatic compounds of the present invention are not limited thereto.

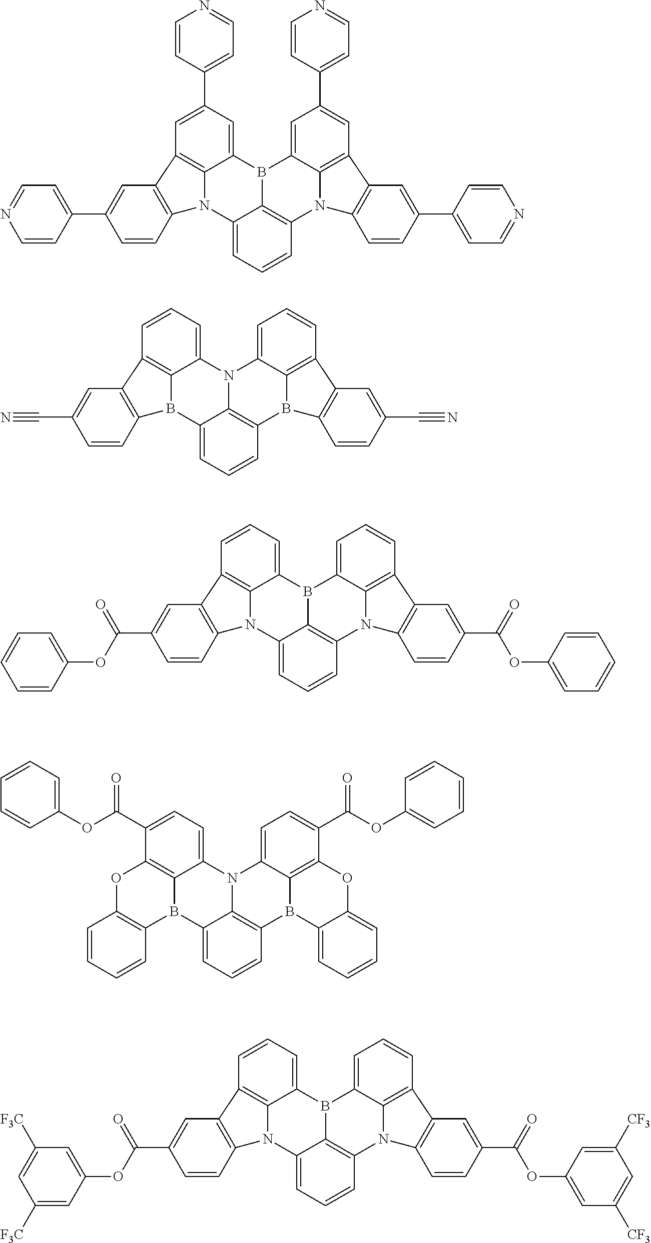

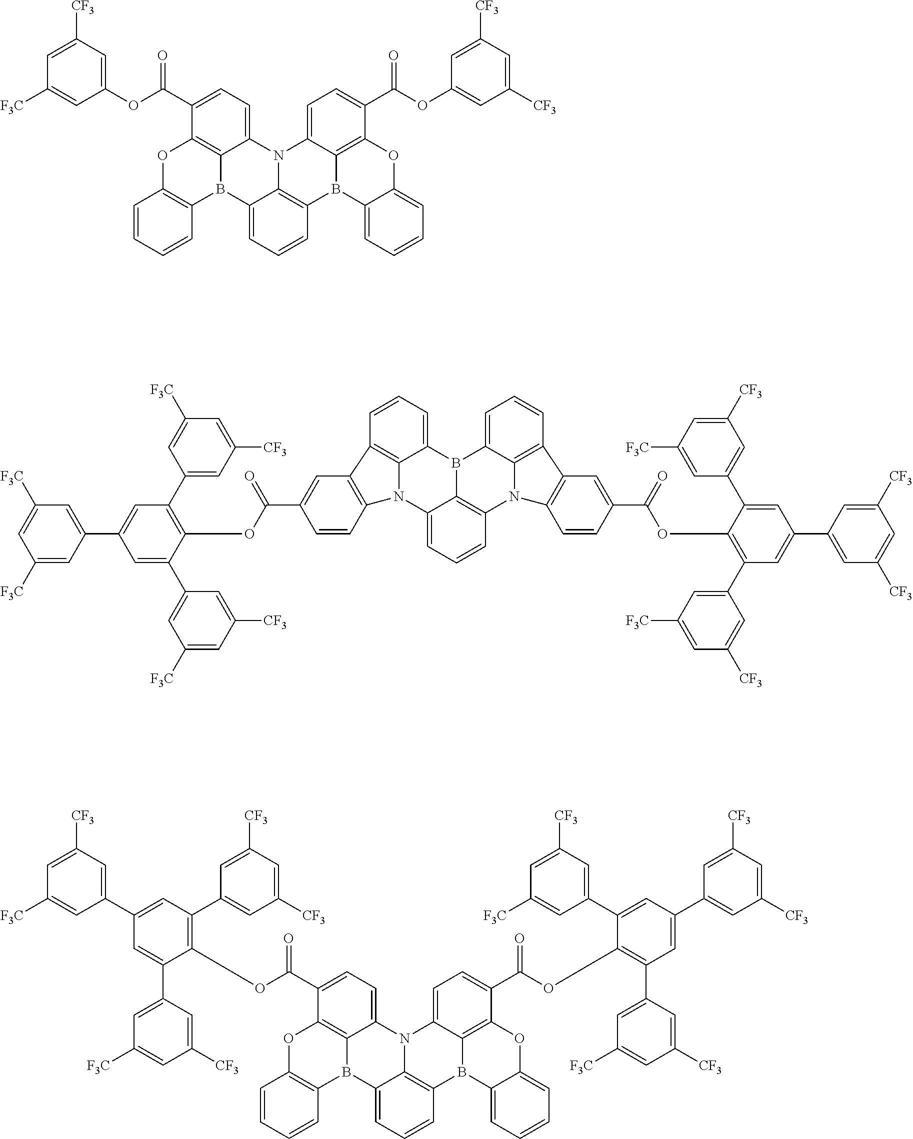

The polycyclic aromatic compounds of the present invention can be produced by reference to the methods described in, for example, JP 2020-097561 A, WO 2015/102118, and WO 2019/164340. That is, a halogen compound is reacted with a boron raw material in the presence of butyllithium to obtain a polycyclic aromatic compound of interest. However, the present invention is not limited thereto.

Furthermore, there is a method of forming a carbon-carbon bond by using a coupling reaction of a halogenated derivative with boronic acid or a boronated derivative to introduce an aryl or heteroaryl group, but the present invention is not limited thereto. Similarly, there is a method of introducing an electron-attracting group by, for example, using a halogenated derivative having a previously substituted electron-attracting group as a raw material or introducing an electron-attracting group by various reactions after structure formation, but the present invention is not limited thereto.

### (Polycyclic Aromatic Compound According to Another Aspect of the Present Invention)

In addition, a polycyclic aromatic compound according to another aspect of the present invention is a compound represented by the general formula (11) or the general formula (12), wherein the compound has at least one electron-attracting group.

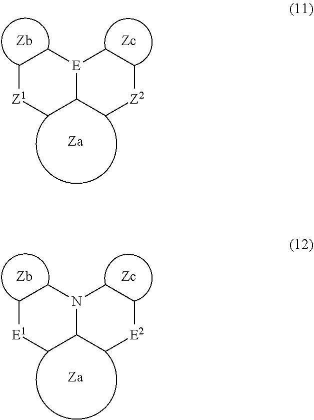

In the general formula (11) or the general formula (12), the rings Za, Zb, and Zc independently represent a substituted or unsubstituted aryl ring having 6 to 30 ring-forming carbon atoms or a substituted or unsubstituted heteroaryl ring having 6 to 30 ring-forming carbon atoms.

In the general formula (11), Z¹ and Z² are independently oxygen, NRa (a nitrogen atom bearing a Ra substituent), or sulfur. In cases where Z¹ is NRa, the substituent Ra, together with the ring Za or the ring Zb, optionally forms a ring. In cases where Z² is NRa, the substituent Ra, together with the ring Za or the ring Zc, optionally forms a ring. E is boron, phosphorus, SiRa (a silicon atom bearing a Ra substituent), or P═O.

In the general formula (12), E¹ and E² are independently BRa (a boron atom bearing a Ra substituent), PRa (a phosphorus atom bearing a Ra substituent), SiRa₂ (a silicon atom bearing two Ra substituents), P(═O)Ra₂ (a phosphine oxide bearing two Ra substituents) or P(═S)Ra₂ (a phosphine sulfide bearing two Ra substituents), or S(═O) or S(═O)₂. In cases where E¹ is BRa, PRa, SiRa₂, P(═O)Ra₂, or P(═S)Ra₂, the substituent Ra, together with the ring Za or the ring Zb, optionally forms a ring. In cases where E² is BRa, PRa, SiRa₂, P(═O)Ra₂, or P(═S)Ra₂, the substituent Ra, together with the ring Za or the ring Zc, optionally forms a ring.

The above substituents Ra independently represent a substituted or unsubstituted aryl, a substituted or unsubstituted heteroaryl, or a substituted or unsubstituted alkyl. The compound represented by the general formula (11) or the general formula (12) has at least one electron-attracting group.

A compound represented by the general formula (11) is a compound represented by the general formula (1) described above and having at least one electron-attracting group. A compound represented by the general formula (12) is a compound represented by the general formula (2) described above and having at least one electron-attracting group. Each group on the compound represented by the general formula (11) or the general formula (12) is given the same description as the groups on the compound represented by the general formula (1) or the general formula (2).

Since the compound represented by the general formula (11) or the general formula (12) has at least one electron-attracting group, the compound represented by the general formula (11) or the general formula (12) has a lower electron density than that in the absence of the electron-attracting group. This increases the stability of the compound represented by the general formula (11) or the general formula (12) against singlet oxygen and, consequently, particularly increases the durability of the compound. Therefore, the compound represented by the general formula (11) or the general formula (12), whether or not having a HOMO level of not more than −5.7 eV, is effective to provide a polycyclic aromatic compound and a color conversion composition which are suitable as color conversion materials and can provide both high color reproduction accuracy and high durability.

### <Color Conversion Composition>

Preferably, a color conversion composition according to an embodiment of the present invention converts incident light from an illuminant, such as a light source, into light of a wavelength different from that of the incident light, comprising a polycyclic aromatic compound of the present invention as described above and a binder resin. In this context, the phrase “converts incident light into light of a wavelength different from that of the incident light” preferably means converting incident light into light of a wavelength longer than that of the incident light.

The color conversion composition according to the embodiment of the present invention may appropriately comprise, in addition to a polycyclic aromatic compound of the present invention, other compounds as needed. For example, the color conversion composition may comprise an assistant dopant such as rubrene to increase the energy transfer efficiency from excitation light to the polycyclic aromatic compound of the present invention. Additionally, in cases where the polycyclic aromatic compound of the present invention is expected to emit different colors of light in addition to the original color of light, a desired organic luminescent material, for example an organic luminescent material such as a coumarin derivative or a rhodamine derivative, may be added to the color conversion composition. In addition to an organic luminescent material, a combination of known luminescent materials such as inorganic fluorescent materials, fluorescent pigments, fluorescent dyes, and semiconductor nanocrystals may be added to the color conversion composition.

Examples of the organic luminescent material other than the polycyclic aromatic compound of the present invention are shown below, but the present invention is not specifically limited thereto.

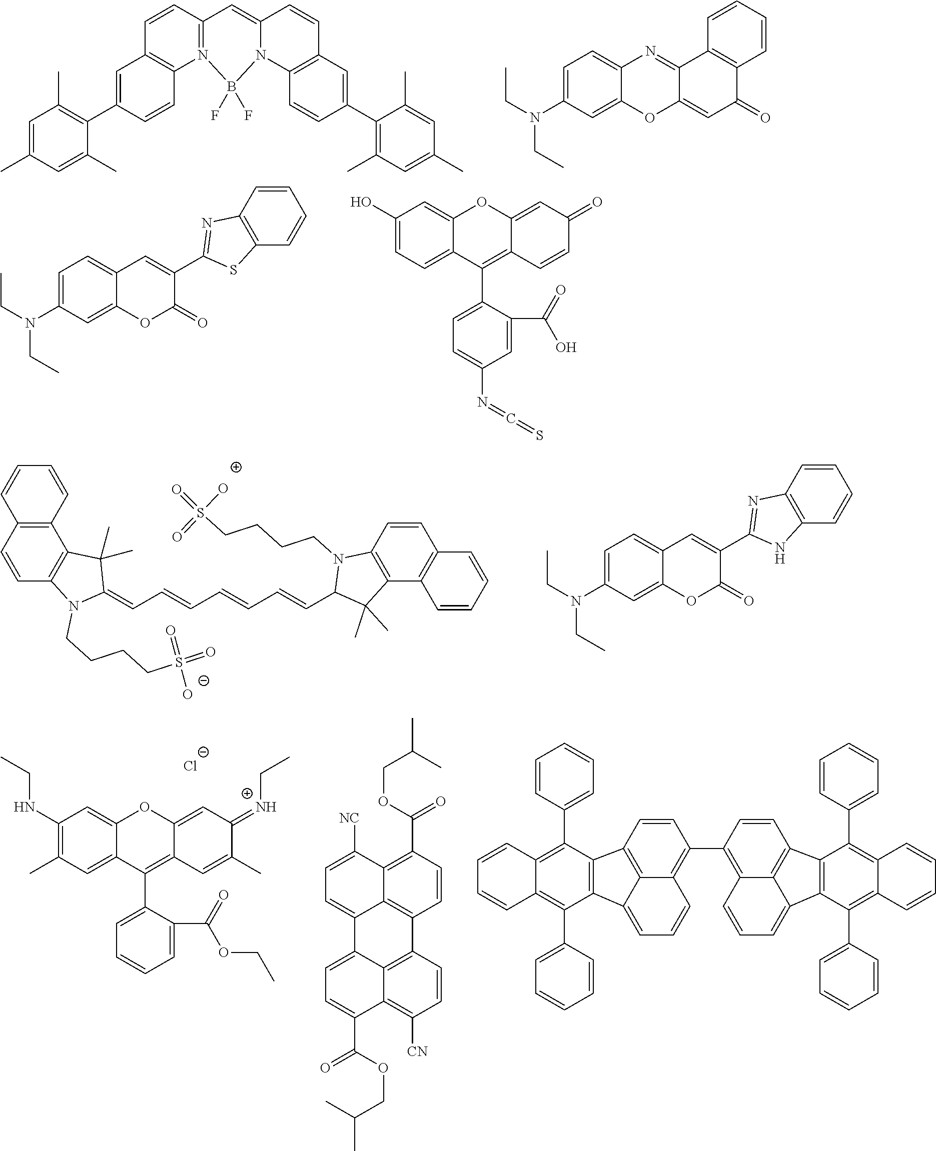

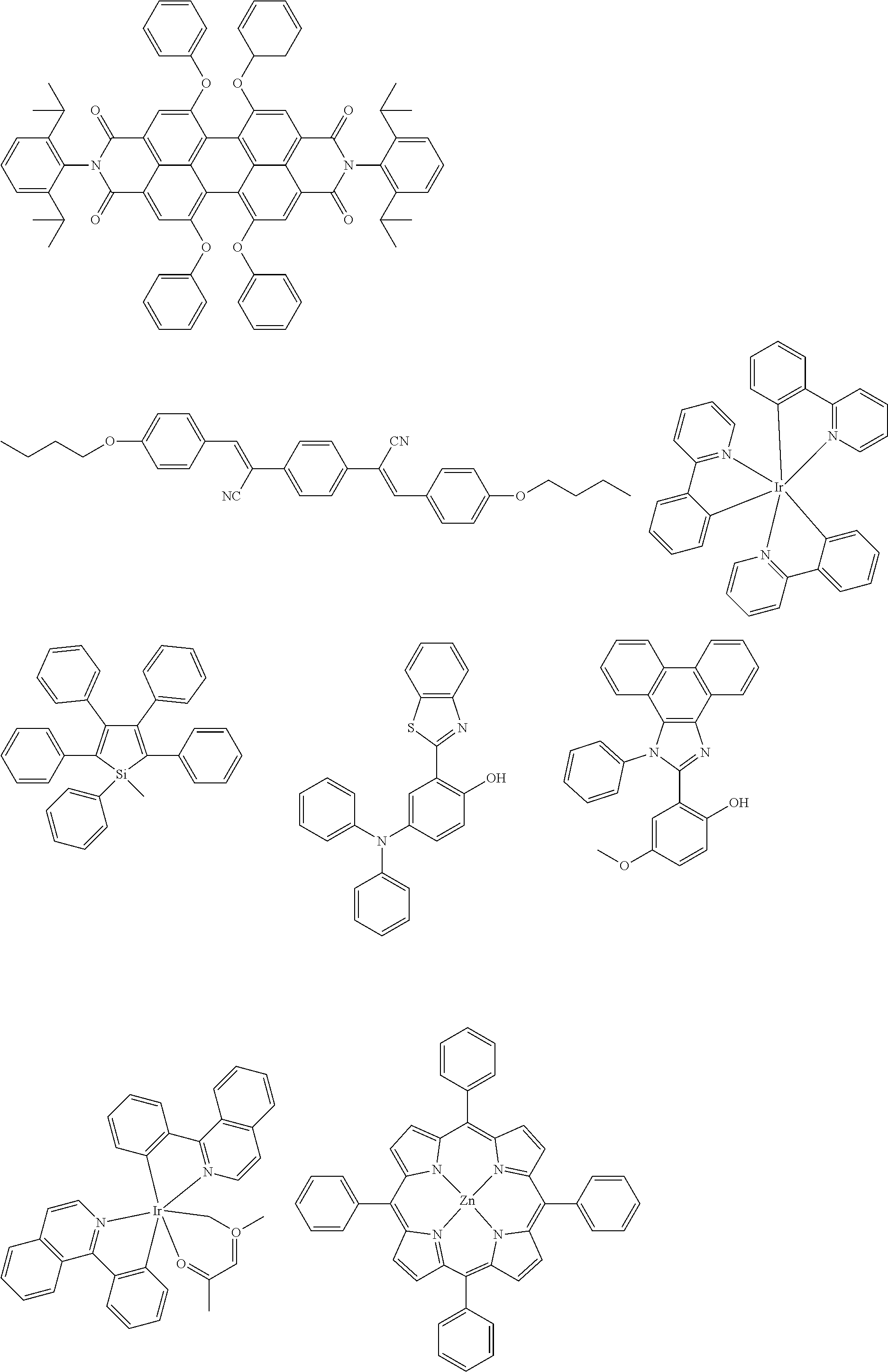

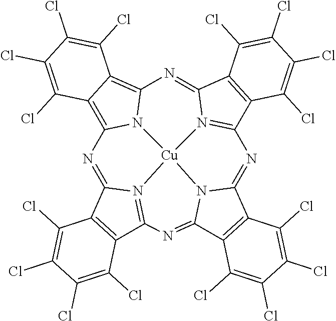

In the present invention, the color conversion composition preferably emits green light when exposed to excitation light. In addition, the color conversion composition preferably emits red light when exposed to excitation light.

### (Binder Resin)

The binder resin becomes the continuous phase and should be a material with excellent formability and processability, transparency, heat resistance, and the like. Examples of the binder resin include known binder resins, including photocurable resist materials containing reactive vinyl groups, such as acrylic, methacrylic, poly(vinyl cinnamate)-based, and cyclic rubber-based resists; and epoxy resins, silicone resins (including cured (cross-linked) organopolysiloxane materials such as silicone rubbers and silicone gels), urea resins, fluorocarbon resins, polycarbonate resins, acrylic resins, urethane resins, melamine resins, polyvinyl resins, polyamide resins, phenolic resins, polyvinyl alcohol resins, cellulose resins, aliphatic ester resins, aromatic ester resins, aliphatic polyolefin resins, and aromatic polyolefin resins. In addition, a copolymer resin of the monomers can be used as the binder resin. A binder resin useful for a color conversion composition and a color conversion sheet according to the embodiment of the present invention can be obtained by appropriately designing these resins. Among these resins, thermoplastic resins are even much preferred because of the ease of sheet forming. Among thermoplastic resins, epoxy resins, silicone resins, acrylic resins, ester resins, olefin resins, or mixtures thereof are suitable for use from the viewpoint of transparency, heat resistance, and the like. In addition, acrylic resins, ester resins, and cycloolefin resins are particularly preferred thermoplastic resins from the viewpoint of durability.

Preferred examples of the binder resin include those described in, for example, WO 2016/190283, WO 2017/61337, WO 2018/43237, WO 2019/21813, and WO 2019/188019.

In addition, the binder resin may be combined with additives such as a dispersing or leveling agent to stabilize the coating quality, while the binder resin may be combined with an adhesion promoter or the like, such as a silane coupling agent, as a sheet surface modifier. Furthermore, the binder resin can be combined with inorganic particles, such as silica or silicone particles, as a color conversion material anti-sedimentation agent.

In a color conversion composition for producing a color conversion sheet according to an embodiment of the present invention, the binder resin is preferably combined with a hydrosilylation retardant such as acetylenic alcohol as an auxiliary component to extend pot life by preventing curing at normal temperature. Additionally, the binder resin may be combined with particles such as fumed silica, glass powder, or quartz powder; an inorganic filler or pigment such as titanium oxide, zirconium oxide, barium titanate, or zinc oxide; a flame retardant, a heat-resistant agent, an antioxidant, a dispersing agent, a solvent, an adhesion promoter such as a silane coupling agent or a titanium coupling agent, and the like, as needed, provided that the effect of the invention is not impaired.

### (Solvent)

The color conversion composition according to the embodiment of the present invention may comprise a solvent. The solvent is not specifically limited, provided that the solvent can be used to control the viscosity of the flowable resin and does not have an extreme effect on the light emission and durability of a luminescent material. Examples of such a solvent include toluene, methyl ethyl ketone, methyl isobutyl ketone, hexane, acetone, terpineol, texanol, methyl cellosolve, butyl carbitol, butyl carbitol acetate, and propylene glycol monomethyl ether acetate. A combination of two or more of these solvents may be used. Among these solvents, toluene is particularly suitable for use because the degradation of the polycyclic aromatic compound of the present invention is not affected by toluene and only a tiny amount of the solvent remains after the polycyclic aromatic compound is dried.

### (Other Component)

The color conversion composition according to the embodiment of the present invention may comprise, in addition to a polycyclic aromatic compound of the present invention as described above and a binder resin, other components (additives) such as a photostabilizer, an antioxidant, a process/heat stabilizer, a light-resistant stabilizer such as an ultraviolet absorber, scattering particles, silicone particles, and a silane coupling agent.

Examples of the photostabilizer include, but are not specifically limited to, tertiary amines, catechol derivatives, nickel compounds, and complexes and organic acid salts containing at least one transition metal selected from the group consisting of Sc, V, Mn, Fe, Co, Cu, Y, Zr, Mo, Ag, and lanthanoids. In addition, the photostabilizers may be used individually or in combination.

Examples of the antioxidant include, but are not specifically limited to, phenolic antioxidants such as 2,6-di-tert-butyl-p-cresol and 2,6-di-tert-butyl-4-ethylphenol. In addition, these antioxidants may be used individually or in combination.

Examples of the process/heat stabilizer include, but are not specifically limited to, phosphoric stabilizers, such as tributyl phosphite, tricyclohexyl phosphite, triethylphosphine, and diphenylbutylphosphine. In addition, these stabilizers may be used individually or in combination.

Examples of the light-resistant stabilizer include, but are not specifically limited to, benzotriazoles, such as 2-(5-methyl-2-hydroxyphenyl)benzotriazole and 2-[2-hydroxy-3,5-bis(α,α-dimethylbenzyl)phenyl]-2H-benzotriazole. In addition, these light-resistant stabilizers may be used individually or in combination.

The scattering particles are preferably, for example, inorganic particles having a refractive index of 1.7 to 2.8. Examples of the inorganic particles include titania, zirconia, alumina, ceria, tin oxide, indium oxide, iron oxide, zinc oxide, aluminum nitride, sulfides of aluminum, tin, titanium, or zirconium, and hydroxides of titanium or zirconium.

Preferably, the contents of these additives in the color conversion composition according to the embodiment of the present invention may vary depending on the molar absorption coefficients, luminescence quantum yields, and absorption intensities at the excitation wavelengths of the compounds, and the thickness and transmittance of a color conversion sheet produced and are typically not less than 1.0×10⁻³ part by weight and not more than 30 parts by weight relative to 100 parts by weight of the binder resin. Furthermore, the contents of these additives are more preferably not less than 1.0×10⁻² part by weight and not more than 15 parts by weight, even more preferably not less than 1.0×10⁻¹ part by weight and not more than 10 parts by weight, relative to 100 parts by weight of the binder resin.

### <Method for Producing Color Conversion Composition>

As an example, a method of producing a color conversion composition according to an embodiment of the present invention is described below. In this production method, predetermined amounts of, for example, a polycyclic aromatic compound of the present invention, a binder resin, and a solvent as described above are mixed. The above components are combined to a predetermined composition and later homogeneously mixed and dispersed by a mixing and kneading machine, such as a homogenizer, planetary centrifugal mixer, three-roll bender, ball mill, planetary ball mill, or bead mill, to obtain a color conversion composition. The foam is preferably removed under vacuum or reduced pressure after or while the above components are mixed and dispersed. In addition, a specific component may be added in advance, or a treatment such as aging may be performed. The solvent can be removed by an evaporator to achieve a desired solid concentration.

### <Color Conversion Sheet>

Preferably, a color conversion sheet according to an embodiment of the present invention converts incident light from an illuminant, such as a light source, into light of a wavelength different from that of the incident light, comprising a polycyclic aromatic compound of the present invention as described above and a binder resin. In this context, the phrase “converts incident light into light of a wavelength different from that of the incident light” preferably means converting incident light into light of a wavelength longer than that of the incident light.

In the present invention, the color conversion sheet preferably comprises a layer comprising a color conversion composition as described above or a cured product thereof. Preferably, the color conversion sheet comprises a cured product of the color conversion composition as a layer obtained by curing the color conversion composition (a layer composed of a cured product of the color conversion composition). Examples of representative structures of the color conversion sheet include the following four structures.

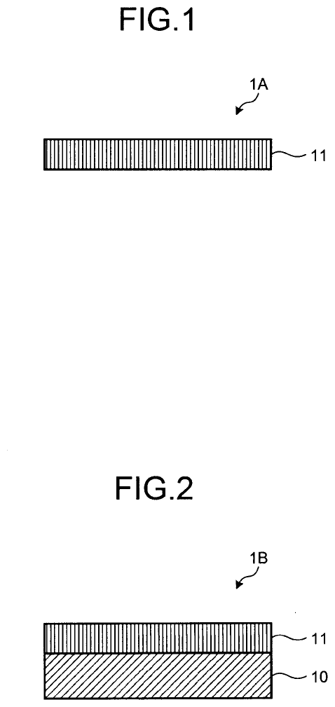

FIG. 1 is a schematic cross-sectional view depicting the first example of a color conversion sheet according to an embodiment of the present invention. As shown in FIG. 1, the color conversion sheet 1A of the first example is a monolayer film composed of a color conversion layer 11. The color conversion layer 11 is a layer composed of a cured product of a color conversion composition as described above.

FIG. 2 is a schematic cross-sectional view depicting the second example of a color conversion sheet according to an embodiment of the present invention. As shown in FIG. 2, the color conversion sheet 1B of the second example is a laminate composed of a base material layer 10 and a color conversion layer 11. In this example of the structure of the color conversion sheet 1B, the color conversion layer 11 is placed on the base material layer 10.

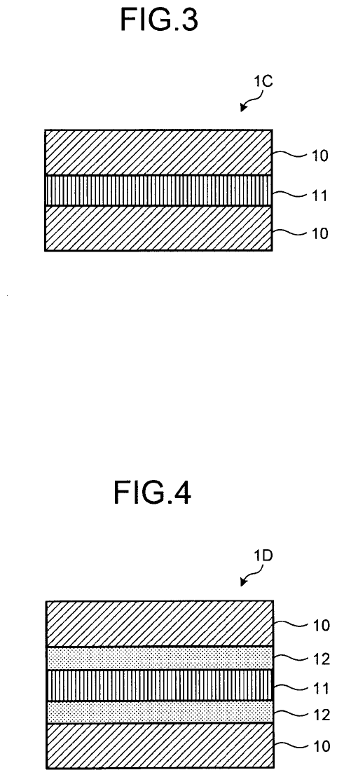

FIG. 3 is a schematic cross-sectional view depicting the third example of a color conversion sheet according to an embodiment of the present invention. As shown in FIG. 3, the color conversion sheet 1C of the third example is a laminate composed of multiple base material layers 10 and a color conversion layer 11. In this example of the structure of the color conversion sheet 1C, the color conversion layer 11 is sandwiched between the multiple base material layers 10.

FIG. 4 is a schematic cross-sectional view depicting the fourth example of a color conversion sheet according to an embodiment of the present invention. As shown in FIG. 4, the color conversion sheet 1D of the fourth example is a laminate composed of multiple base material layers 10, a color conversion layer 11, and multiple barrier films 12. In this example of the structure of the color conversion sheet 1D, the color conversion layer 11 is sandwiched between the multiple barrier films 12, and the laminate composed of the color conversion layer 11 and the multiple barrier films 12 is further sandwiched between the multiple base material layers 10. That is, the color conversion sheet 1D may include the barrier films 12, as shown in FIG. 4, to prevent the color conversion layer 11 from being degraded by oxygen, water moisture, or heat.

### (Base Material Layer)

For example, a known and not specifically limited metal, film, glass, ceramic, or paper material may be used for a base material layer (e.g., the base material layer 10 shown in FIGS. 2 to 4). Among these materials, a glass material or a resin film is suitable for use because a color conversion sheet having such a base material layer is easily made or formed. In addition, when a film is used as a base material layer, a high-strength film is preferred to prevent, for example, possible breakage. A resin film is preferred from the viewpoint of the required properties and economy, particularly, and a plastic film selected from the group consisting of polyethylene terephthalate (PET), polyphenylene sulfide, polycarbonate, and polypropylene films is particularly preferred from the viewpoint economy and ease of handling. Additionally, a polyimide film is preferred from the viewpoint heat resistance when a resulting color conversion sheet is dried or subjected to compression molding at a temperature of 200° C. or higher with an extruder. The surface of the base material layer can be pre-treated with mold release to facilitate release of the film.

The thickness of the base material layer is not specifically limited, but the lower limit of the thickness is preferably not less than 25 μm and more preferably not less than 38 μm. Additionally, the upper limit of the thickness is preferably not more than 5000 μm and more preferably not more than 3000 μm.

### (Color Conversion Layer)

A color conversion composition produced by the method described above can be applied to a substrate, such as a base material layer or a barrier film, and dried to form a color conversion layer (e.g., the color conversion layer 11 shown in FIGS. 1 to 4).

The thickness of the color conversion layer is not specifically limited, but is preferably not less than 10 μm and not more than 1000 μm. The lower limit of the thickness of the color conversion layer is more preferably not less than 30 μm. In addition, the upper limit of the thickness of the color conversion layer is more preferably not more than 200 μm, still more preferably not more than 100 μm, and particularly preferably not more than 50 μm. In the present invention, the thickness of a color conversion sheet is a film thickness (an average film thickness) measured by the thickness measurement method A based on mechanical scanning in JIS K7130 (1999) “Plastics—Film and sheeting—Determination of thickness”.

The color conversion sheet of the present invention may comprise a single color conversion layer or two or more color conversion layers. In cases where the color conversion sheet comprises two or more color conversion layers, at least one of the layers preferably comprises a polycyclic aromatic compound of the present invention.

The color conversion layer may comprise, in addition to a polycyclic aromatic compound of the present invention as described above and a binder resin, other components (additives) such as a photostabilizer, an antioxidant, a process/heat stabilizer, a light-resistant stabilizer such as an ultraviolet absorber, scattering particles, silicone particles, and a silane coupling agent.

### (Barrier Film)

A barrier film (e.g., the barrier film 12 shown in FIG. 4) is appropriately used, for example, to provide an improved gas barrier property to the color conversion layer. The barrier film may be, for example, a film of an inorganic oxide, such as silicon oxide, aluminum oxide, titanium oxide, tantalum oxide, zinc oxide, tin oxide, indium oxide, yttrium oxide, or magnesium oxide, an inorganic nitride, such as silicon nitride, aluminum nitride, titanium nitride, or silicon carbide nitride, or a mixture thereof; a metal oxide film or nitride film composed of any of the above metal compounds and other elements, or a film of a resin, such as polyvinylidene chloride, an acrylic resin, a silicon-based resin, a melamine resin, a urethane resin, a fluorine-based resin, or a polyvinyl alcohol resin made of, for example, saponified vinyl acetate. In addition, a barrier film having a barrier function against water moisture may be, for example, a film of a resin, such as polyethylene, polypropylene, nylon, polyvinylidene chloride, a vinylidene chloride/vinyl chloride copolymer, a vinylidene chloride/acrylonitrile copolymer, fluorine-based resin, or a polyvinyl alcohol resin made of, for example, saponified vinyl acetate.

A barrier film may be provided on both surfaces of the color conversion layer 11, as in the case of the barrier film 12 shown in FIG. 4, or on one surface of the color conversion layer 11. In addition, an auxiliary layer having a function such as anti-reflection function, anti-glare function, hard coating property (antifriction function), antistatic function, anti-fouling function, electromagnetic shielding function, infrared cutting function, ultraviolet cutting function, polarization function, or color changing function may be further provided depending on the functions required for a color conversion sheet.

### (Other Films)

The color conversion sheet according to the embodiment of the present invention may further comprise, for example, a double brightness enhancing film (DBEF), a diffusion sheet, a prism sheet, and/or a wavelength-selective reflection film. Preferred examples of the wavelength-selective reflection film are those described in, for example, WO 2017/164155 and JP 2018-81250 A.

### <Light Source Unit>

A light source unit according to an embodiment of the present invention comprises at least a light source and a color conversion sheet as described above. The light source which the light source unit according to the embodiment of the present invention comprises is a source which emits the excitation light described above. The installation of a light source and a color conversion sheet is not limited to a specific way, and the light source and the color conversion sheet can be placed in close contact with each other, or the light source and the color conversion sheet can be placed away from each other, that is, in the remote phosphor configuration. In addition, the light source unit may further comprise a color filter to increase color purity.

### (Light Source)

Any type of excitation light emitted from a light source can be used as long as the wavelength of the excitation light is within the absorption wavelength band of a mixed luminescent material such as a polycyclic aromatic compound of the present invention. For example, any excitation light such as that from a fluorescent light source, such as a hot cathode tube, cold cathode tube, or inorganic electroluminescence (EL), an organic EL light source, an LED light source, an incandescent light source, or sunlight can be used in principle. In particular, the light from an LED light source is a preferable excitation light.

The excitation light can have one emission peak or two or more emission peaks, but excitation light with a single emission peak is preferred to increase color purity. In addition, arbitrary combinations of multiple excitation light sources with different emission peaks can be used.

In display and lighting applications, the light source of the excitation light is preferably a light-emitting diode with a maximum emission wavelength in the range of 430 nm to 500 nm to increase the color purity of the blue light. Furthermore, the light source preferably has a maximum emission wavelength in the range of 440 nm to 470 nm. The excitation light having a wavelength in the range of 430 nm to 500 nm has a relatively small amount of excitation energy and can prevent a luminescent material such as a polycyclic aromatic compound of the present invention from being degraded.

The light source unit of the present invention can be used in applications such as display, lighting, interior, sign, signboard applications and is particularly suitable for use in display and lighting applications.

### <Display and Lighting Device>

A display according to an embodiment of the present invention comprises at least a color conversion sheet as described above. For example, a light source unit as described above comprising a light source, a color conversion sheet, and the like is used as a backlight unit in displays such as liquid crystal displays. In addition, a lighting device according to an embodiment of the present invention comprises at least a color conversion sheet as described above. For example, this lighting device is configured to emit white light, wherein the configuration comprises a blue LED light source in combination with a color conversion sheet that converts the blue light from the blue LED light source to light of a longer wavelength as a light source unit.

### <Light-Emitting Device>

In an embodiment of the present invention, a light-emitting device comprises an anode, a cathode, and an organic layer located between the anode and the cathode. The organic layer emits light when electrical energy is applied to the light-emitting device. A polycyclic aromatic compound of the present invention can be used in any layer of the light-emitting device, but is preferably used in the light-emitting layer of the light-emitting device because the polycyclic aromatic compound has a high fluorescence quantum yield. In particular, since the polycyclic aromatic compound has a high fluorescence quantum yield, the polycyclic aromatic compound is preferably used as a dopant material for the light-emitting layer described above.

### EXAMPLES

The present invention will be described below by the following examples, but the present invention is not limited to the examples. Compounds G-1, G-2, and G-101 to G-103 in the following examples and comparative examples are compounds shown below.

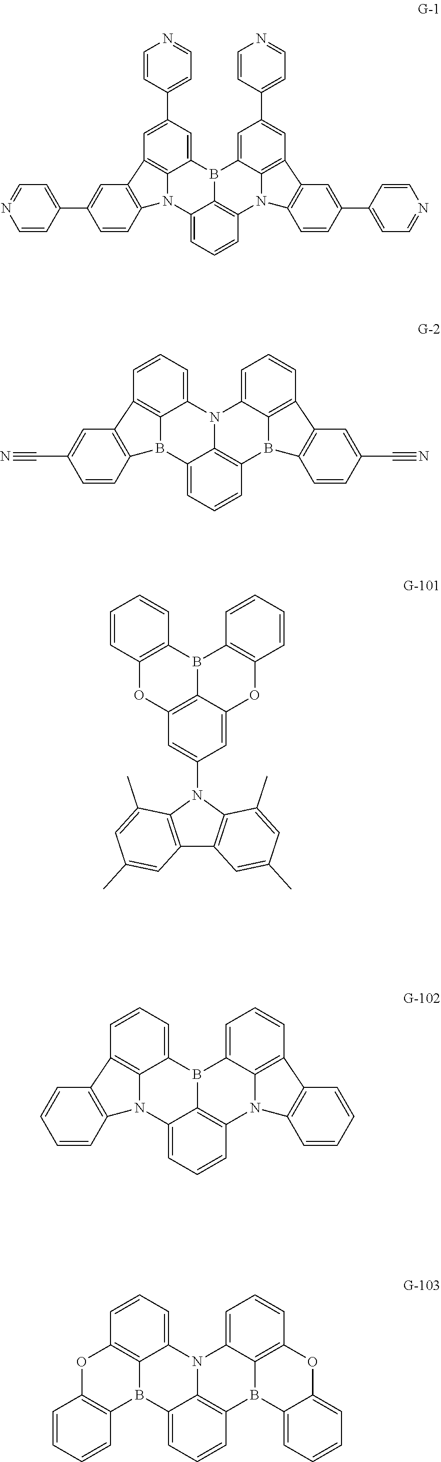

The evaluation methods used in the structural analysis of the examples and comparative examples are described below.

### <Measurement of Fluorescence Spectrum>

When the fluorescence spectrum of a compound was measured, the compound was dissolved in toluene to a concentration of 1×10⁻⁵ mol/L and then excited at a wavelength of 460 nm to measure the fluorescence spectrum using an F-2500 fluorescence spectrophotometer (manufactured by Hitachi, Ltd.).

### <Measurement of Luminescence Quantum Yield>

When the luminescence quantum yield of a compound was measured, the compound was dissolved in toluene to a concentration of 1×10⁻⁵ mol/L and then excited at a wavelength of 460 nm to measure the luminescence quantum yield using an absolute PL quantum yield measurement system (Quantaurus-QY; manufactured by Hamamatsu Photonics K.K.).

### (Homo Level)

For the calculation of the HOMO level of each compound of Example or Comparative Example, the geometry optimization of the compound was simulated using the B3LYP density functional theory with the 6-31G(d) basis set in a general purpose computational chemistry program “Gaussian 16” program package (produced by Gaussian, Inc.). The HOMO level of the compound was calculated based on the optimized geometry using the B3LYP density functional theory with the 6-311++G(d,p) basis set.

### Synthesis Example 1

The method of synthesizing compound G-1 is described below as Synthesis Example 1 of the present invention.

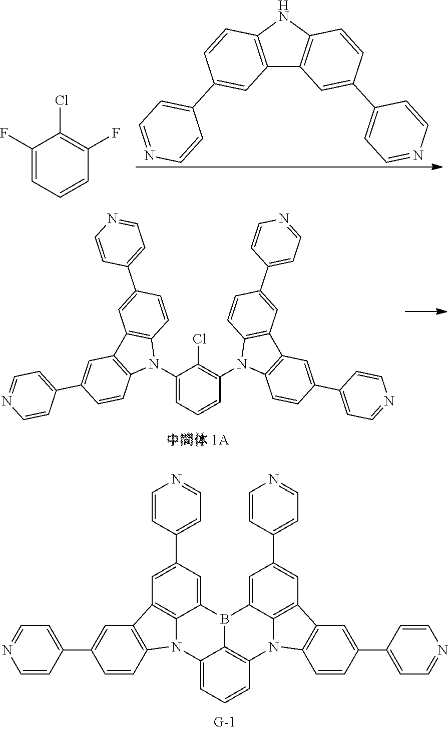

In the synthesis method of compound G-1, 2-bromo-1,3-difluorobenzene (2.0 g), dipyridylcarbazole (10.0 g), potassium carbonate (5.0 g), and N-methyl-2-pyrrolidone (25 mL) were stirred in a flask with heating at 170° C. under nitrogen atmosphere for 10 hours. Hereinafter, N-methyl-2-pyrrolidone is abbreviated as NMP. After the reaction in the solution in the flask ceased, the reaction solution in the flask was cooled to room temperature, and water and toluene were added to the cooled reaction solution, and the resulting reaction solution was separated into an organic solvent layer and an aqueous layer. The organic solvent layer was evaporated under reduced pressure to remove the solvent, and the residue was purified by silica gel column chromatography to give intermediate 1A.

A flask containing intermediate 1A (10.0 g) and xylene (30 mL) was cooled to −40° C., and a 2.6 M hexane solution of n-butyllithium (4.0 mL) was added dropwise to the flask. After completion of the dropwise addition, the solution in the flask was warmed to room temperature. The solution was then cooled again to −40° C. before boron tribromide (1.1 mL) was added to the solution. The solution in the flask was then warmed to room temperature, stirred for 13 hours, and cooled to 0° C. N,N-diisopropylethylamine (3.1 mL) was then added to the solution in the flask, and the resulting mixture was stirred while heating at 130° C. for 5 hours. After the reaction was completed, the reaction solution in the flask was cooled to room temperature, and an aqueous solution of sodium acetate cooled in an ice bath was added to the reaction solution. The resulting mixture was stirred, and the reaction solution was filtered under vacuum after stirring to collect a precipitated solid. The collected solid was washed sequentially with water, methanol, and heptane and further recrystallized in chlorobenzene to give a compound of interest, compound G-1 (0.8 g).

Compounds G-2 and G-101 to G-103 can be synthesized by modifying the various raw materials for the above compound.

In each of the following examples and comparative examples, an electric current was applied to a backlight unit comprising the respective color conversion sheet, a blue LED device (emission peak wavelength: 445 nm) and the light guide panel to illuminate the blue LED device for the evaluation of initial emission characteristics using a spectral radiance meter (CS-1000; manufactured by KONICA MINOLTA, Inc.), after the respective color conversion sheet was placed on one surface of the light guide panel and a prism sheet was further placed on the color conversion sheet. To evaluate the initial emission characteristics, the brightness of the light from the blue LED device was set to 800 cd/m² without inserting the color conversion sheet as a default setting. After the default setting was completed, the color conversion sheet was inserted and continuously exposed to the light from the blue LED device at room temperature to evaluate the optical durability by measuring the time required for a 5% decrease in brightness.

### Example 1-1

Example 1-1 of the present invention is an example of using a polycyclic aromatic compound according to the embodiment described above as a luminescent material (a color conversion material). In Example 1-1, an acrylic resin was used as a binder resin, and a mixture of 100 parts by weight of the acrylic resin, 0.25 parts by weight of compound G-1 as a luminescent material, and 400 parts by weight of toluene as a solvent was prepared. The resulting mixture was then stirred and defoamed at 300 rpm for 20 minutes using a planetary stirring and defoaming mixer “MAZERUSTAR KK-400” (manufactured by Kurabo Industries Ltd.) to obtain a color conversion composition.

Similarly, a polyester resin was used as a binder resin, and a mixture of 100 parts by weight of the polyester resin and 300 parts by weight of toluene as a solvent was prepared. The mixed solution was then stirred and deformed at 300 rpm for 20 minutes using a planetary stirring and defoaming mixer “MAZERUSTAR KK-400” (manufactured by Kurabo Industries Ltd.) to obtain an adhesive composition.

Next, the color conversion composition obtained as described above was applied to a first base material layer, “Lumirror” U48 (thickness: 50 μm; manufactured by Toray Industries, Inc.), using a slit die coating machine and was heated at 100° C. for 20 minutes and dried to form a layer (A) with an average film thickness of 16 μm.

Similarly, the adhesive conversion composition obtained as described above was applied to a second base material layer, the PET base material layer in the light diffusion film “Chemical Matte” 125 PW (thickness: 138 μm; manufactured by KIMOTO Co., Ltd.), using a slit die coating machine and was heated at 100° C. for 20 minutes and dried to form a layer (B) with an average film thickness of 48 μm.

Then, these two layers (A) and (B) were hot laminated together so that the color conversion layer of layer (A) was in direct contact with the adhesive layer of layer (B) to produce a color conversion sheet having a laminate configuration of “first base material layer/color conversion layer/adhesive layer/second base material layer/light diffusion layer”.

When the color conversion sheet was continuously exposed to the light from the blue LED device at room temperature, the time required for a 5% decrease in brightness was 1010 hours. The luminescent material of Example 1-1 and the results of the evaluation of the luminescent material are shown in Table 1 below.

### Example 1-2 and Comparative Examples 1-1 to 1-3

In Example 1-2 of the present invention and Comparative Examples 1-1 to 1-3 as controls against the present invention, color conversion sheets were produced and evaluated in the same manner as in Example 1-1, except that the compounds listed in Table 1 below (compounds G-2 and G-101 to G-103) were appropriately used as luminescent materials. The luminescent materials of Example 1-2 and Comparative Examples 1-1 to 1-3 and the results of the evaluation of the luminescent materials are shown in Table 1. A longer period of optical durability is more preferable. Specifically, an optical durability of 500 hours or more is preferable.

TABLE 1

| | | HOMO | Peak | Half- | | Optical |
|---|---|---|---|---|---|---|
| | Luminescent | level | wavelength | width | Quantum | durability |
| | material | (eV) | (nm) | (nm) | yield | (h) |
| Example 1-1 | G-1 | −6.0 | 526 | 23 | 0.95 | 1010 |
| Example 1-2 | G-2 | −6.5 | 528 | 23 | 0.96 | 2200 |
| Comparative | G-101 | −5.3 | 460 | 80 | 0.80 | 100 |
| Example 1-1 | | | | | | |
| Comparative | G-102 | −5.6 | 510 | 22 | 0.95 | 300 |
| Example 1-2 | | | | | | |
| Comparative | G-103 | −5.6 | 522 | 23 | 0.97 | 320 |
| Example 1-3 | | | | | | |

The present invention will also be described below by the following examples, but the present invention is not limited to the examples. Compounds G-3 to G-8 and G-104 to G-107 in the following examples and comparative examples are compounds shown below.

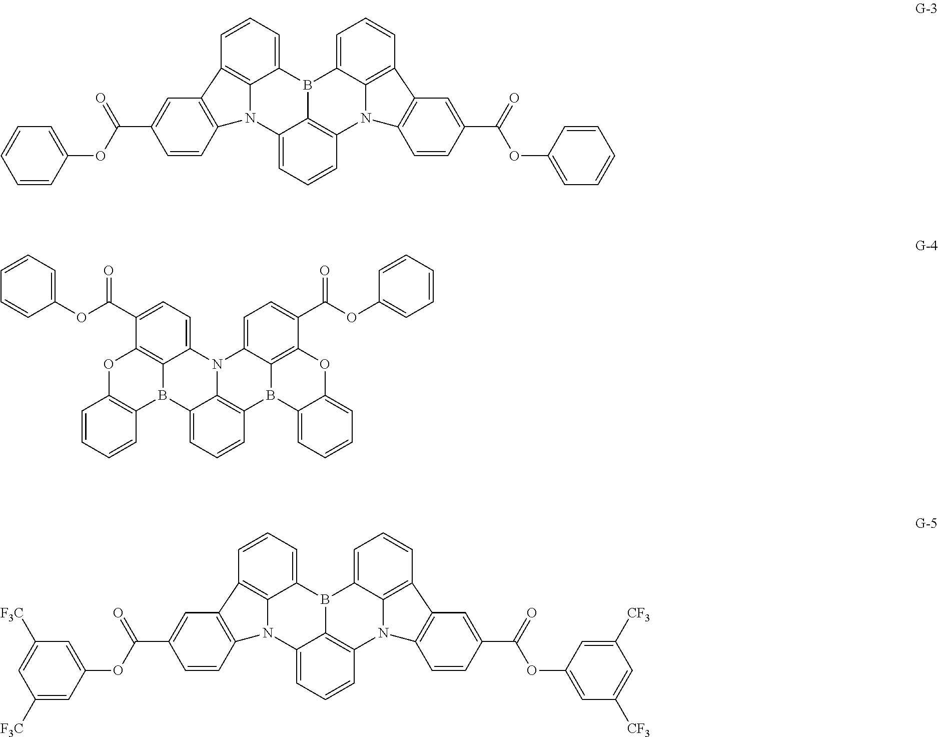 [SMILES: O=C(Oc1ccccc1)c1ccc2c(c1)c1cccc3c1n2-c1cccc2c1B3c1cccc3c4cc(C(=O)Oc5ccccc5)ccc4n-2c13 ; O=C(Oc1ccccc1)c1ccc2c3c1Oc1ccccc1B3c1cccc3c1N2c1ccc(C(=O)Oc2ccccc2)c2c1B3c1ccccc1O2 ; O=C(Oc1cc(C(F)(F)F)cc(C(F)(F)F)c1)c1ccc2c(c1)c1cccc3c1n2-c1cccc2c1B3c1cccc3c4cc(C(=O)Oc5cc(C(F)(F)F)cc(C(F)(F)F)c5)ccc4n-2c13]

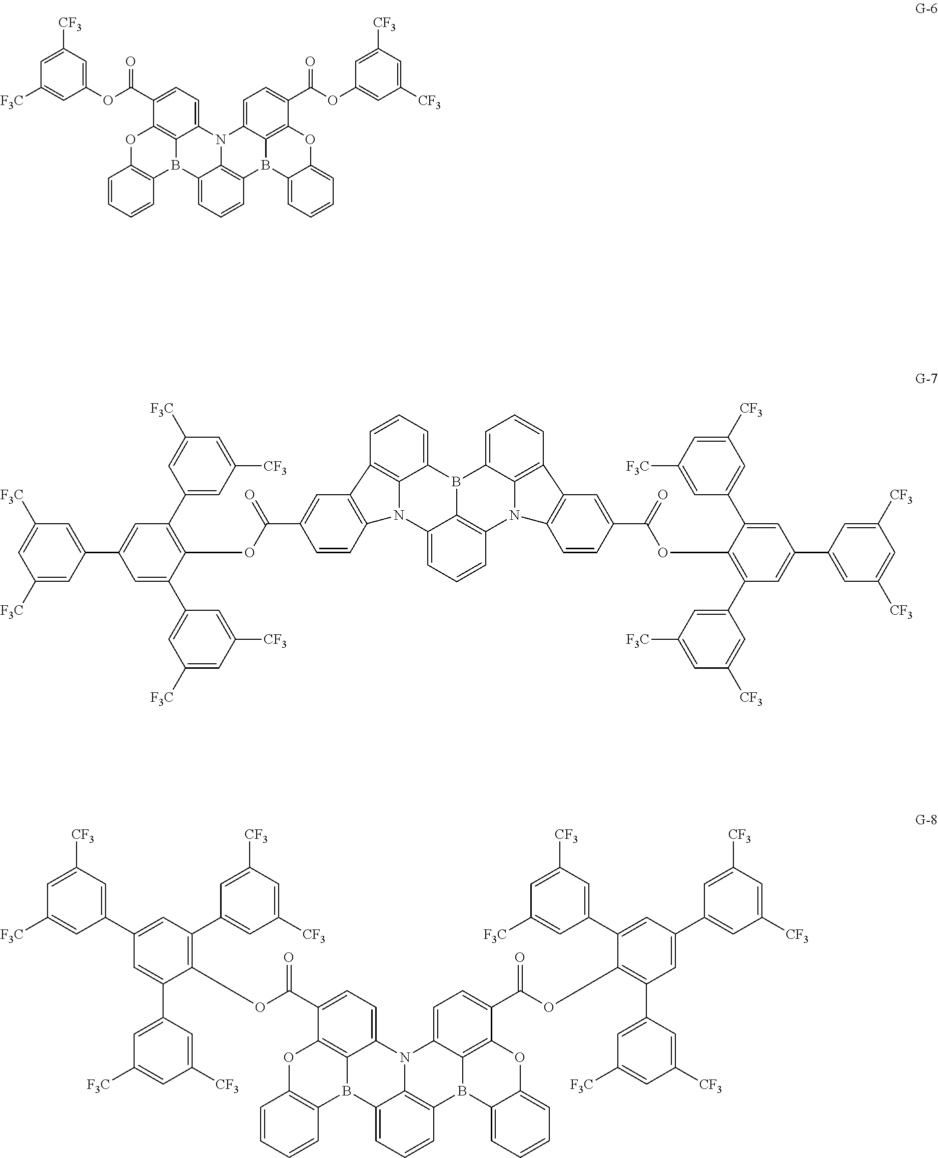

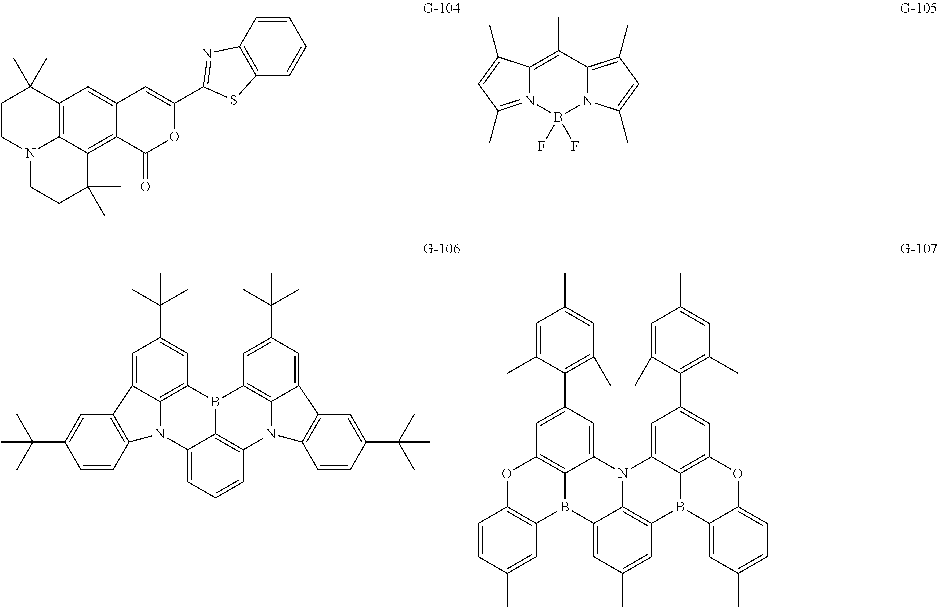

The evaluation methods used in the structural analysis of the examples and comparative examples are described below.

### <Measurement of Fluorescence Spectrum>

When the fluorescence spectrum of a compound was measured, the compound was dissolved in toluene to a concentration of 1×10⁻⁵ mol/L and then excited at a wavelength of 460 nm to measure the fluorescence spectrum using an F-2500 fluorescence spectrophotometer (manufactured by Hitachi, Ltd.).

### <Measurement of Luminescence Quantum Yield>

When the luminescence quantum yield of a compound was measured, the compound was dissolved in toluene to a concentration of 1×10⁻⁵ mol/L and then excited at a wavelength of 460 nm to measure the luminescence quantum yield using an absolute PL quantum yield measurement system (Quantaurus-QY; manufactured by Hamamatsu Photonics K.K.).

### Synthesis Example 2

The method of synthesizing compound G-3 is described below as Synthesis Example 2 of the present invention.

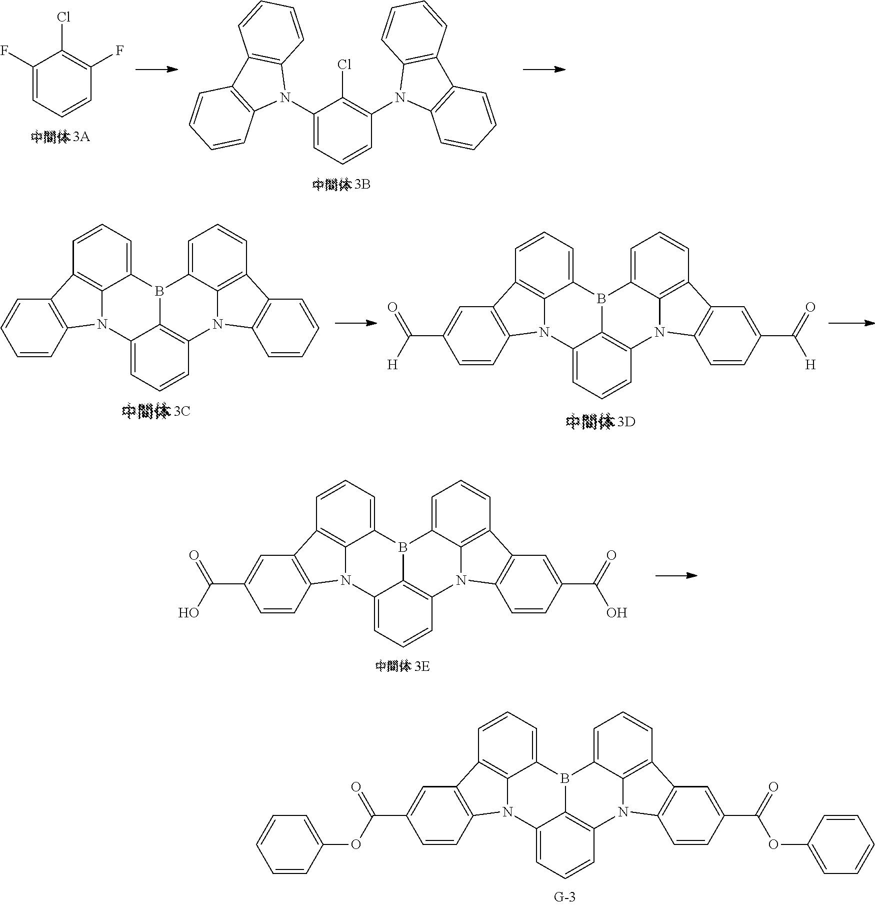 [SMILES: Fc1cccc(F)c1Cl ; Clc1c(-n2c3ccccc3c3ccccc32)cccc1-n1c2ccccc2c2ccccc21 ; c1cc2c3c(c1)-n1c4ccccc4c4cccc(c41)B3c1cccc3c4ccccc4n-2c13 ; O=Cc1ccc2c(c1)c1cccc3c1n2-c1cccc2c1B3c1cccc3c4cc(C=O)ccc4n-2c13 ; O=C(O)c1ccc2c(c1)c1cccc3c1n2-c1cccc2c1B3c1cccc3c4cc(C(=O)O)ccc4n-2c13 ; O=C(Oc1ccccc1)c1ccc2c(c1)c1cccc3c1n2-c1cccc2c1B3c1cccc3c4cc(C(=O)Oc5ccccc5)ccc4n-2c13]

In the synthesis method of compound G-3, 2-bromo-1,3-difluorobenzene (20.0 g), carbazole (50.0 g), potassium carbonate (50.0 g), and NMP (250 mL) were stirred in a flask with heating at 170° C. under nitrogen atmosphere for 10 hours. After the reaction in the solution in the flask ceased, the reaction solution in the flask was cooled to room temperature, and water and toluene were added to the cooled reaction solution, and the resulting reaction solution was separated into an organic solvent layer and an aqueous layer. The organic solvent layer was evaporated under reduced pressure to remove the solvent, and the residue was purified by silica gel column chromatography to give intermediate 3A.

A flask containing intermediate 3A (44.2 g) and xylene (300 mL) was cooled to −40° C., and a 2.6 M hexane solution of n-butyllithium (40.4 mL) was added dropwise to the flask. After completion of the dropwise addition, the solution in the flask was warmed to room temperature. The solution was then cooled again to −40° C. before boron tribromide (10.2 mL) was added to the solution. The solution in the flask was then warmed to room temperature, stirred for 13 hours, and cooled to 0° C. N,N-diisopropylethylamine (30.8 mL) was then added to the solution in the flask, and the resulting mixture was stirred while heating at 130° C. for 5 hours. After the reaction was completed, the reaction solution in the flask was cooled to room temperature, and an aqueous solution of sodium acetate cooled in an ice bath was added to the reaction solution. The resulting mixture was stirred, and the reaction solution was filtered under vacuum after stirring to collect a precipitated solid. The collected solid was washed sequentially with water, methanol, and heptane and further recrystallized in chlorobenzene to give intermediate 3B.

Dimethylformamide (10 mL) and dichloroethane (200 mL) were mixed in a flask, and the resulting mixture was cooled to 0° C. POCl₃ (10 mL) was slowly added dropwise to the cooled mixture under nitrogen atmosphere, and the resulting solution was stirred in the flask for 30 minutes at normal temperature. After the stirring was completed, intermediate 3B (10 g) was added to the reaction solution, and the resulting mixture was heated to 60° C. and stirred for 1 hour. The solution of intermediate 3B was cooled to normal temperature and then poured into a mixture of ice and a saturated aqueous solution of sodium hydroxide. The resulting mixture was stirred at normal temperature for 2 hours and then extracted with chloroform, and the organic solvent layer was separated. The organic solvent layer was dried over anhydrous magnesium sulfate, filtered, and then evaporated under reduced pressure to remove the solvent from the organic solvent layer. The residue was then filtered through a silica gel column to give intermediate 3C.

Intermediate 3C (6.0 g) and NH₂SO₃H (1.2 g) were dissolved in tetrahydrofuran, and NaClO₂ (1.1 g) dissolved in water was slowly added dropwise to the resulting solution at 0° C. The resulting solution was stirred at normal temperature for 1 hour, and a saturated solution of Na₂S₂O₃ was added to the solution. The resulting mixed solution was then extracted with chloroform, and the organic solvent layer was separated. The organic solvent layer was dried over anhydrous magnesium sulfate, filtered, and then evaporated under reduced pressure to remove the solvent from the organic solvent layer. The residue was then filtered through a silica gel column to give intermediate 3D.

Intermediate 3E (5.0 g), phenol (1.0 g), and DMAP (0.1 g) were dissolved in dichloromethane, and DCC (2.2 g) dissolved in dichloromethane was slowly added dropwise to the resulting solution at 0° C. The resulting solution was stirred at normal temperature for 12 hours, and a saturated aqueous solution of sodium hydroxide was added to the solution. The resulting mixed solution was extracted with chloroform, and the organic solvent layer was separated. The organic solvent layer was dried over anhydrous magnesium sulfate, filtered, and then evaporated under reduced pressure to remove the solvent from the organic solvent layer. The residue was then filtered through a silica gel column to a compound of interest, compound G-3 (4.3 g).

Compounds G-4 to G-8 and G-104 to G-107 can be synthesized by modifying the various raw materials for the above compound.

In each of the following examples and comparative examples, an electric current was applied to a backlight unit comprising the respective color conversion sheet, a blue LED device (emission peak wavelength: 445 nm) and the light guide panel to illuminate the blue LED device for the evaluation of initial emission characteristics using a spectral radiance meter (CS-1000; manufactured by KONICA MINOLTA, Inc.), after the respective color conversion sheet was placed on one surface of a light guide panel and a prism sheet was further placed on the color conversion sheet. To evaluate the initial emission characteristics, the brightness of the light from the blue LED device was set to 800 cd/m² without inserting the color conversion sheet as a default setting. After the default setting was completed, the color conversion sheet was inserted and continuously exposed to the light from the blue LED device at room temperature to evaluate the optical durability by measuring the time required for a 5% decrease in brightness.

### Example 2-1

Example 2-1 of the present invention is an example of using a polycyclic aromatic compound according to the embodiment described above as a luminescent material (a color conversion material). In Example 2-1, an acrylic resin was used as a binder resin, and a mixture of 100 parts by weight of the acrylic resin, 0.25 parts by weight of compound G-3 as a luminescent material, and 400 parts by weight of toluene as a solvent was prepared. The resulting mixture was then stirred and defoamed at 300 rpm for 20 minutes using a planetary stirring and defoaming mixer “MAZERUSTAR KK-400” (manufactured by Kurabo Industries Ltd.) to obtain a color conversion composition.

Similarly, a polyester resin was used as a binder resin, and a mixture of 100 parts by weight of the polyester resin and 300 parts by weight of toluene as a solvent was prepared. The mixed solution was then stirred and deformed at 300 rpm for 20 minutes using a planetary stirring and defoaming mixer “MAZERUSTAR KK-400” (manufactured by Kurabo Industries Ltd.) to obtain an adhesive composition.

Next, the color conversion composition obtained as described above was applied to a first base material layer, “Lumirror” U48 (thickness: 50 μm; manufactured by Toray Industries, Inc.), using a slit die coating machine and was heated at 100° C. for 20 minutes and dried to form a layer (A) with an average film thickness of 16 μm.

Similarly, the adhesive conversion composition obtained as described above was applied to a second base material layer, the PET base material layer in the light diffusion film “Chemical Matte” 125 PW (thickness: 138 μm; manufactured by KIMOTO Co., Ltd.), using a slit die coating machine and was heated at 100° C. for 20 minutes and dried to form a layer (B) with an average film thickness of 48 μm.

Then, these two layers (A) and (B) were hot laminated together so that the color conversion layer of layer (A) was in direct contact with the adhesive layer of layer (B) to produce a color conversion sheet having a laminate configuration of “first base material layer/color conversion layer/adhesive layer/second base material layer/light diffusion layer”.

When the color conversion sheet was used to convert the color of the light from the blue LED device (blue light), green light emission with high color purity was obtained, with a peak wavelength of 527 nm and a half-width of the emission spectrum at the peak wavelength of 28 nm, but this is an excerpt of the result focusing only on the green light region. In addition, the luminescence quantum yield was 0.95. Moreover, when the color conversion sheet was continuously exposed to the light from the blue LED device at room temperature, the time required for a 5% decrease in brightness 810 hours. The luminescent material of Example 2-1 and the results of the evaluation of the luminescent material are shown in Table 2 below.

### Examples 2-2 to 2-6 and Comparative Examples 2-1 to 2-4

In Examples 2-2 to 2-6 of the present invention and Comparative Examples 2-1 to 2-4 as controls against the present invention, color conversion sheets were produced and evaluated in the same manner as in Example 2-1, except that the compounds listed in Table 2 below (compounds G-4 to G-8 and G-104 to G-107) were appropriately used as luminescent materials. The luminescent materials of Examples 2-2 to 2-6 and Comparative Examples 2-1 to 2-4 and the results of the evaluation of the luminescent materials are shown in Table 2. A longer period of optical durability is more preferable. Specifically, an optical durability of 800 hours or more is preferable.

TABLE 2

| | | HOMO | Peak | Half- | | Optical |
|---|---|---|---|---|---|---|
| | Luminescent | level | wavelength | width | Quantum | durability |
| | material | (eV) | (nm) | (nm) | yield | (h) |
| Example 2-1 | G-3 | −5.9 | 527 | 28 | 0.95 | 810 |
| Example 2-2 | G-4 | −5.9 | 528 | 29 | 0.98 | 950 |
| Example 2-3 | G-5 | −6.2 | 527 | 28 | 0.94 | 1500 |
| Example 2-4 | G-6 | −6.2 | 528 | 28 | 0.97 | 1750 |
| Example 2-5 | G-7 | −6.2 | 527 | 28 | 0.95 | 2400 |
| Example 2-6 | G-8 | −6.2 | 528 | 29 | 0.98 | 2760 |
| Comparative | G-104 | −5.4 | 540 | 40 | 0.70 | 80 |
| Example 2-1 | | | | | | |
| Comparative | G-105 | −5.8 | 528 | 29 | 0.82 | 70 |
| Example 2-2 | | | | | | |
| Comparative | G-106 | −5.4 | 527 | 29 | 0.94 | 210 |
| Example 2-3 | | | | | | |
| Comparative | G-107 | −5.4 | 527 | 28 | 0.97 | 280 |
| Example 2-4 | | | | | | |

### INDUSTRIAL APPLICABILITY

As seen above, a polycyclic aromatic compound, a color conversion composition, a color conversion sheet, a light source unit, a display, and a lighting device according to the present invention are suitable for achieving both improved color reproduction accuracy and increased durability.

### REFERENCE SIGNS LIST

1A, 1B, 1C, 1D color conversion sheet
10 base material layer
11 color conversion layer
12 barrier film

1. A polycyclic aromatic compound, wherein the compound is observed to emit light having a peak wavelength in the range of 500 nm to 750 nm when exposed to excitation light, has a HOMO level of not more than −5.7 eV, and emits delayed fluorescence.

2. The polycyclic aromatic compound of claim 1, wherein the polycyclic aromatic compound has a HOMO level of not more than −6.0 eV.

3. The polycyclic aromatic compound of claim 1, wherein the polycyclic aromatic compound has a HOMO level of not more than −6.2 eV.

4. The polycyclic aromatic compound of claim 1, wherein the polycyclic aromatic compound has a HOMO level of not more than −6.5 eV.

5. The polycyclic aromatic compound of claim 1, wherein at the emission peak wavelength of the polycyclic aromatic compound, the half-width of the emission spectrum is not more than 40 nm.

6. The polycyclic aromatic compound of claim 1, wherein the polycyclic aromatic compound is a compound represented by the general formula (1) or the general formula (2) 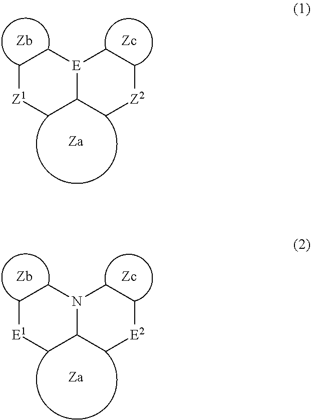
(wherein the rings Za, Zb, and Zc independently represent a substituted or unsubstituted aryl ring having 6 to 30 ring-forming carbon atoms or a substituted or unsubstituted heteroaryl ring having 6 to 30 ring-forming carbon atoms; Z¹ and Z² are independently oxygen, NRa (a nitrogen atom bearing a Ra substituent), or sulfur; in cases where Z¹ is NRa, the substituent Ra, together with the ring Za or the ring Zb, optionally forms a ring; in cases where Z² is NRa, the substituent Ra, together with the ring Za or the ring Zc, optionally forms a ring; E is boron, phosphorus, SiRa (a silicon atom bearing a Ra substituent), or P═O; E¹ and E² are independently BRa (a boron atom bearing a Ra substituent), PRa (a phosphorus atom bearing a Ra substituent), SiRa₂ (a silicon atom bearing two Ra substituents), P(═O)Ra₂ (a phosphine oxide bearing two Ra substituents) or P(═S)Ra₂ (a phosphine sulfide bearing two Ra substituents), or S(═O) or S(═O)₂; in cases where E¹ is BRa, PRa, SiRa₂, P(═O)Ra₂, or P(═S)Ra₂, the substituent Ra, together with the ring Za or the ring Zb, optionally forms a ring; in cases where E² is BRa, PRa, SiRa₂, P(═O)Ra₂, or P(═S)Ra₂, the substituent Ra, together with the ring Za or the ring Zc, optionally forms a ring; the substituents Ra independently represent a substituted or unsubstituted aryl, a substituted or unsubstituted heteroaryl, or a substituted or unsubstituted alkyl).

7. The polycyclic aromatic compound of claim 6, wherein the compound represented by the general formula (1) or the general formula (2) comprises at least one electron-attracting group.

8. The polycyclic aromatic compound of claim 7, wherein the compound represented by the general formula (1) or the general formula (2) comprises two or more electron-attracting groups.

9. The polycyclic aromatic compound of claim 7, wherein the electron-attracting group(s) is/are cyano group(s), acyl group(s), ester group(s), amide group(s), sulfonyl group(s), sulfonate group(s), or sulfonamide group(s).

10. The polycyclic aromatic compound of claim 7, wherein the electron-attracting group(s) is/are ester group(s).

11. The polycyclic aromatic compound of claim 6, wherein the Z¹ and the Z² are oxygen or NRa.

12. The polycyclic aromatic compound of claim 6, wherein
the E is boron; and
the E¹ and the E² are Bra.

13. The polycyclic aromatic compound of claim 6, wherein the ring Za, the ring Zb, and the ring Zc are benzene rings.

14. The polycyclic aromatic compound of claim 1, wherein the polycyclic aromatic compound is observed to emit light having a peak wavelength in the range of 500 nm to 580 nm when exposed to excitation light.

15. The polycyclic aromatic compound of claim 1, wherein the polycyclic aromatic compound is observed to emit light having a peak wavelength in the range of 580 nm to 750 nm when exposed to excitation light.

16. A color conversion composition that converts incident light into light of a wavelength different from that of the incident light, comprising:
the polycyclic aromatic compound of claim 1; and
a binder resin.

17. A color conversion sheet that converts incident light into light of a wavelength different from that of the incident light, comprising:
the polycyclic aromatic compound of claim 1; and
a binder resin.

18. The color conversion sheet of claim 17, further comprising a barrier film(s).

19. A light source unit, comprising:
a light source; and
the color conversion sheet of claim 17.

20. The light source unit of claim 19, wherein the light source is a light-emitting diode with a maximum emission wavelength in the range of 430 nm to 500 nm.

21. A display, comprising the color conversion sheet of claim 17.

22. A lighting device, comprising the color conversion sheet of claim 17.
